(19) United States
(12) Patent Application Publication
(10) Pub. No.: US 2026/0311761 A1
(43) Pub. Date: Oct. 8, 2026

(54) Fabrication Method for a Memory Structure Including High Density Three-Dimensional NOR Memory Strings of Junctionless Ferroelectric Storage Transistors

(71) Applicant: SUNRISE MEMORY CORPORATION, San Jose, CA (US)

(72) Inventor: Eli Harari, Saratoga, CA (US)

(21) Appl. No.: 19/711,118

(22) Filed: Jun. 17, 2026

Related U.S. Application Data
(63) Continuation of application No. 18/175,277, filed on Feb. 27, 2023, now Pat. No. 12,694,931.
(60) Provisional application No. 63/315,797, filed on Mar. 2, 2022.

(51) Int. Cl. G11C 16/04; H10B 51/10; H10B 51/20; H10D 30/01; H10D 30/67; H10D 30/69; H10D 64/68

(52) U.S. Cl. CPC G11C 16/0483; H10B 51/10; H10B 51/20; H10D 30/0415; H10D 30/6755; H10D 30/701; H10D 64/689

(57) ABSTRACT

A memory structure including three-dimensional NOR memory strings and method of fabrication is disclosed. In some embodiments, a memory structure includes randomly accessible ferroelectric storage transistors organized as horizontal NOR memory strings. The NOR memory strings are formed over a semiconductor substrate in multiple scalable memory stacks of thin-film storage transistors. The ferroelectric storage transistors are junctionless field-effect transistors having a ferroelectric polarization layer formed adjacent a semiconductor oxide layer as the channel region. The three-dimensional memory stacks are manufactured in a process that uses a sacrificial layer and access shafts to perform channel separation through a backside selective etch process.

### CROSS REFERENCE TO RELATED APPLICATIONS

This application is a continuation of U.S. Patent Application No. 18/175,277, entitled MEMORY STRUCTURE INCLUDING HIGH DENSITY THREE-DIMENSIONAL NOR MEMORY STRINGS OF JUNCTIONLESS FERROELECTRIC STORAGE TRANSISTORS AND METHOD OF FABRICATION, filed Feb. 27, 2023, which claims priority to U.S. Provisional Patent Application No. 63/315,797, entitled MEMORY STRUCTURE INCLUDING HIGH DENSITY THREE-DIMENSIONAL NOR MEMORY STRINGS OF JUNCTIONLESS FERROELECTRIC STORAGE TRANSISTORS AND METHOD OF FABRICATION, filed Mar. 2, 2022, which applications are incorporated herein by reference in their entireties for all purposes.

### FIELD OF THE INVENTION

The invention relates to high-density memory structures, and in particular, the present invention relates to high-density, low read-latency memory structures formed by interconnected thin-film storage elements (e.g., 3-dimensional array of thin-film storage transistors), including those organized as NOR-type memory strings (“NOR memory strings”), and fabrication processes thereof.

### BACKGROUND OF THE INVENTION

A NOR-type memory string includes storage transistors that share a common source region and a common drain region, where each storage transistor can be individually addressed and accessed. U.S. Patent 10,121,553 (the ‘553 Patent), entitled “Capacitive-Coupled Non-Volatile Thin-film Transistor NOR Strings in Three-Dimensional Arrays,” issued on November 6, 2018, discloses storage transistors (or memory transistors) organized as 3-dimensional arrays of NOR memory strings formed above a planar surface of a semiconductor substrate. The ‘553 Patent is hereby incorporated by reference in its entirety for all purposes. In the ‘553 Patent, a NOR memory string includes numerous thin-film storage transistors that share a common bit line and a common source line. In particular, the ‘553 Patent discloses a NOR memory string that includes (i) a common source region and a common drain region both running lengthwise along a horizontal direction and (ii) gate electrodes for the storage transistors each running along a vertical direction. In the present description, the term “vertical” refers to the direction normal to the surface of a semiconductor substrate, and the term “horizontal” refers to any direction that is parallel to the surface of that semiconductor substrate. In a 3-dimensional array, the NOR memory strings are provided on multiple planes (e.g., 8 or 16 planes) above the semiconductor substrate, with the NOR memory strings on each plane arranged in rows. For a charge-trap type storage transistor, data is stored in each storage transistor using a charge storage film as the gate dielectric material. For examples, the charge storage film includes a tunneling dielectric layer, a charge trapping layer and a blocking layer, which can be implemented as a multilayer including silicon oxide or oxynitride, silicon-rich nitride, and silicon oxide, arranged in this order and referred to as an ONO layer. An applied electrical field across the charge storage film adds or removes charge from charge traps in the charge trapping layer, altering the threshold voltage of the storage transistor to encode a given logical state to the storage transistor.

Advances in electrically polarizable materials (“ferroelectric materials”), especially those that are being used in semiconductor manufacturing processes, suggest new potential applications in ferroelectric memory circuits. For example, the article “Ferroelectricity in Hafnium Oxide: CMOS compatible Ferroelectric Field Effect Transistors,” by T.S. Böscke et al., published in 2011 International Electron Devices Meeting (IEDM), pp. 24.5.1-24.5.4, discloses a ferroelectric field effect transistor (“FeFET”) that uses hafnium oxide as a gate dielectric material. By controlling the polarization direction in a ferroelectric gate dielectric layer, the FeFET may be programmed to have either one of two threshold voltages. Each threshold voltage of the FeFET constitutes a state, for example, a “programmed” state or an “erased” state, that represents a designated logical value. Such an FeFET has application in high-density memory circuits. For example, U.S. Patent No. 9,281,044, entitled “Apparatuses having a ferroelectric field-effect transistor memory array and related method,” by D.V. Nirmal Ramaswamy et al., filed on May 17, 2013, discloses a 3-dimensional array of FeFETs.

### SUMMARY OF THE INVENTION

The present disclosure discloses a memory structure including three-dimensional NOR memory strings of junctionless ferroelectric memory transistors and method of fabrication, substantially as shown in and/or described below, for example in connection with at least one of the figures, as set forth more completely in the claims.

In some embodiments, a three-dimensional memory structure formed above a planar surface of a semiconductor substrate includes an array of thin-film ferroelectric storage transistors being organized as an array of stacks of NOR memory strings, the storage transistors within each NOR memory string sharing a common source layer and a common drain layer, spaced apart by a first isolation layer, with each layer extending along a first direction. The common source layer and the common drain layer each includes a conductive layer formed between the first isolation layer. Each NOR memory string extends along the first direction that is substantially parallel to the planar surface of the semiconductor substrate. The NOR memory strings of each stack are (a) provided one on top of another along a second direction substantially normal to the planar surface, and (b) isolated one from the other memory string by a second isolation layer. A semiconductor oxide layer formed on the sidewalls of each stack of NOR memory strings and, with respect to each NOR memory string within the stack, in contact with the common source layer and the common drain layer of the NOR memory string, thus providing channel regions for the storage transistors of the NOR memory string. A ferroelectric gate dielectric layer is provided adjacent the semiconductor oxide layer. A set of conductors are provided between adjacent stacks of NOR memory strings, each conductor extending along the second direction, and each serving as a common gate electrode for a group of storage transistors in the NOR memory strings of the adjacent stacks. Within a stack of NOR memory strings, the semiconductor oxide layer for the storage transistors of a first NOR memory string are separated from the semiconductor oxide layer for the storage transistors of a second adjacent NOR memory string in the same stack in the second direction.

In other embodiments, a process suitable for use in fabricating a memory structure including storage transistors of a NOR memory string above a planar surface of a semiconductor substrate includes: above the planar surface, repeatedly depositing, alternately and one over another, a multilayer and an inter-layer sacrificial layer, each multilayer including first and second sacrificial layers and a first isolation layer between the first and second sacrificial layers; forming a first set of trenches in the multilayers and the inter-layer sacrificial layers, each trench having (i) a depth that extends along a first direction that is substantially normal to the planar surface, (ii) a length that extends along a second direction that is substantially parallel to the planar surface, (iii) a width that extends along a third direction that is substantially orthogonal to the depth and the length, the length of the trench being substantially greater than its width; and forming a semiconductor oxide layer on the sidewalls of the first set of trenches; forming a second set of trenches in the multilayers and the inter-layer sacrificial layers, each trench in the second set of trenches having substantially the same depth, length and width as the first set of trenches. The first and second set of trenches divide the multilayers into an array of stacks of multilayer strips, each stack being separated from an adjacent stack by one of the trenches. The process further includes replacing the first and second sacrificial layers with first and second conductive layers; and forming the semiconductor oxide layer also on the sidewalls of the second set of trenches.

These and other advantages, aspects and novel features of the present invention, as well as details of an illustrated embodiment thereof, will be more fully understood from the following description and drawings.

### BRIEF DESCRIPTION OF THE DRAWINGS

Various embodiments of the invention are disclosed in the following detailed description and the accompanying drawings. Although the drawings depict various examples of the invention, the invention is not limited by the depicted examples. It is to be understood that, in the drawings, like reference numerals designate like structural elements. Also, it is understood that the depictions in the figures are not necessarily to scale.

FIG. 1, which includes FIG. 1(a), is a perspective view of a memory structure including a 3-dimensional array of NOR memory strings in some embodiments.

FIGS. 2(a) - 2(s), including 2(11) and 2(o1), illustrate a process for fabricating a memory structure including HNOR memory strings in embodiments of the present invention.

FIG. 3 illustrates a memory structure formed using dummy layers for isolating the channel layer for global word line connections in some embodiments.

FIG. 4 is a cross-sectional view of a portion of a memory structure in the X-Y plane illustrating NOR memory strings with precharge transistors in embodiments of the present invention.

FIGS. 5(a) and 5(b) illustrate the detail construction of junctionless ferroelectric storage transistors in alternate embodiments of the present invention.

### DETAILED DESCRIPTION OF THE INVENTION

In embodiments of the present invention, a memory structure includes randomly accessible ferroelectric storage transistors organized as horizontal NOR memory strings. The NOR memory strings are formed over a semiconductor substrate in multiple scalable memory stacks of thin-film storage transistors. The ferroelectric storage transistors in each NOR memory string share a common source line and a common drain line extending in a horizontal direction. The channel layer of the ferroelectric storage transistors is formed on the sidewalls of the memory stacks, in contact with the common source line and the common drain line of each NOR memory string. Gate dielectric layers and gate conductor layers of the storage transistors are formed in a vertical direction in narrow trenches between the memory stacks to form storage transistors in multiple parallel planes of each stack, a storage transistor being formed at each intersection of a gate conductor layer and the common source line and the common drain line of a memory string. In the present description, the term “vertical” refers to the direction normal to the surface of a semiconductor substrate, and the term “horizontal” refers to any direction that is parallel to the surface of that semiconductor substrate.

In embodiments of the present invention, each memory stack includes multiple NOR memory strings formed one on top of another in the vertical direction. In some embodiments, the stacks of NOR memory strings are formed by groups of thin films successively deposited over a planar surface of a semiconductor substrate, each group of thin films being referred to as an “active layer” in the present description. The active layers in each stack of NOR memory strings are provided one on top of another and separated from the other by an inter-layer isolation layer. Each active layer includes conductive layers as the common drain line and the common source line, each line being arranged spaced apart from the other in the vertical direction by a channel spacer dielectric layer. The common drain line and the common line layer may be provided as sacrificial layers during initial processing and replaced by the conductive layers in later processing.

In embodiments of the present disclosure, the ferroelectric storage transistors are thin-film ferroelectric field-effect transistors (FeFETs) having a ferroelectric polarization layer as a gate dielectric layer, the ferroelectric polarization layer being formed adjacent a semiconductor oxide layer as a channel region. The ferroelectric storage transistors include source and drain regions − both formed of a metallic conductive material − in electrical contact with the semiconductor oxide channel region. The ferroelectric storage transistors thus formed are each a junctionless transistor without a p/n junction in the channel and in which the threshold voltage is modulated by the polarization of the mobile carriers in the ferroelectric polarization layer. In the memory structure of the present invention, the ferroelectric storage transistors in each NOR memory string are controlled by individual control gate electrodes to allow each storage transistor to be individually addressed and accessed. In some embodiments, the ferroelectric polarization layer is formed of a doped hafnium oxide material and the semiconductor oxide channel region is formed of an amorphous metal oxide semiconductor material.

In the present description, the term “semiconductor oxide layer” (sometimes also referred to as “oxide semiconductor layer” or “metal oxide semiconductor layer”) as used herein refers to thin film semiconducting materials made from a conductive metal oxide, such as zinc oxide and indium oxide, or any suitable conductive metal oxides with charge-carriers having mobilities that can be modified or modulated using suitable preparation or inclusion of suitable impurities.

In the present embodiments, the storage transistors in the NOR memory strings are ferroelectric field effect transistors including a ferroelectric thin film as the gate dielectric layer, also referred to as the ferroelectric polarization layer or ferroelectric gate dielectric layer or ferroelectric dielectric layer. In a ferroelectric field effect transistor (FeFET), the polarization direction in the ferroelectric gate dielectric layer is controlled by an electric field applied between the transistor drain terminal and the transistor gate electrode, where changes in the polarization direction alters the threshold voltage of the FeFET. In some embodiments, the electric field is applied to both the transistor drain and source terminals, relative to the transistor gate electrode. For example, the FeFET may be programmed to have either one of two threshold voltages, where each threshold voltage of the FeFET can be used to encode a given logical state. For example, the two threshold voltages of the FeFET can be used to encode a “programmed” state and an “erased” state, each representing a designated logical value. In some embodiments, more than two threshold voltages may be established to represent more than two memory states at each FeFET.

The memory structure of the present invention realizes many advantages over known or existing memory structures and devices. First, ferroelectric storage transistors manufactured on vertical walls are very compact and can be manufactured in three-dimensional memory stacks at lower temperatures that are compatible with logic back-end-of-line (BEOL) processes. Ferroelectric storage transistors can operate at lower voltages than conventional charge-trapping storage transistors. These characteristics of the ferroelectric storage transistors enable easy integration of a memory array of three-dimensional horizontal NOR (HNOR) memory strings directly above digital and analog integrated circuits that are built at the surface of a semiconductor substrate. Until recently, ferroelectric transistors had limited endurance. Recent advances in ferroelectric memory research has demonstrated erase/write endurance in excess of 1x10¹¹ cycles as well as fast erase and fast program operations, which enable the use of ferroelectric storage transistors in embedded memory applications. For example, Tan et al. demonstrated ferroelectric memory transistors formed on a crystalline silicon channel with endurance exceeding 10¹⁰ cycles. (See, for example, Ava Jiang Tan et al., “Ferroelectric HfO₂ Memory Transistors with High-K Interfacial Layer and Write Endurance Exceeding 10¹⁰ Cycles,” arXiv:2103.08806 [physics.app-ph], submitted March 16, 2021, available at https://arxiv.org/abs/2103.08806.)

In some embodiments, the ferroelectric storage transistors, as described herein, provide high endurance, long data retention, and relatively low voltage operations for both erase and programming operations (e.g., under +/-5.0 volts). By combining the ferroelectric or polarization characteristics with the 3-dimensional organization (e.g., as the thin-film NOR memory strings described herein), the memory structure of ferroelectric storage transistors of the present invention achieves the additional benefits of high-density, low-cost memory arrays with the advantages of high-speed, randomly accessed memory circuits with low read latency.

Second, the three-dimensional memory structure of the present invention includes ferroelectric storage transistors that use semiconductor oxide layer (or a metal oxide semiconductor layer) as the junctionless channel regions, eliminating the need for heavily doped polysilicon layers for source and drain regions, resulting in a reduced thickness of each active layer in a memory stack as compared to storage transistors formed using traditional polysilicon channel regions with heavily doped semiconductor layers as the source and drain regions. In particular, semiconductor oxide channels have the advantage of a high mobility for greater switching performance and without concern for electron or hole tunneling, as compared to traditional polysilicon channels. Ferroelectric storage transistors with junctionless semiconductor oxide channels also support shorter channel length than is possible with polysilicon doped channels while providing lower channel leakage and reduced GIDL (Gate Induced Drain Leakage) effect.

More specifically, the length of the junctionless channel of the ferroelectric transistor can be significantly shorter than the length of the polysilicon channel, thereby allowing the ferroelectric memory structure of the present invention to be more scalable in stack height, making it easier to deposit and etch multiple layers of three dimensional ferroelectric memory strings that make up ever taller memory stacks. In particular, a thinner active layer results in a reduced aspect ratio (AR) for etching the deep trenches between the memory stacks. In turn, reduced aspect ratios allow building more memory planes within a given total height of the three-dimensional memory structure.

In some embodiments, a memory structure of one or more memory layers (or memory planes) of ferroelectric transistors can be configured to serve as high density embedded memory in logic integrated circuits; the high density is made possible by the fact that the ferroelectric transistors are formed along the vertical walls of memory stack, therefore requiring very little physical space in the horizontal X-Y dimension. For example, the three dimensional ferroelectric memory structure of the present invention can be constructed in the form of a “skyscraper,” allows the formation of a high capacity memory circuit embedded within a logic integrated circuit. Embedding the memory structure of the present invention is made possible by virtue of the relatively low temperatures (typically under 500ºC) required to build the ferroelectric memory stacks, therefore minimizing any damage to the transistors making up the logic integrated circuits sharing the same substrate.

Third, the memory structure of the present invention is formed in a fabrication process where the channel layer is deposited as a continuous conformal layer on the sidewalls of the stacks and subsequently separated and isolated to each memory string in the stack by backside selective etching through access openings provided by an inter-layer sacrificial layer formed between each active layer and to be replaced in subsequent process steps by an inter-layer isolation layer. In one example, the stacks are formed by groups of thin films (active layers) separated by an inter-layer sacrificial layer, such as a silicon germanium or carbon layer, which is to be subsequently replaced by an insulation layer, which can be a dielectric layer or an air gap isolation. During intermediate processing steps, the inter-layer sacrificial layer is removed which provides access openings to the channel layer formed on the sidewall of the stacks at the areas between adjacent active layers. The exposed portion of the channel layer (referred herein as the backside of the channel layer) at each stack is etched using the access openings to separate and isolate the channel layer to each active layer, thereby forming the channel regions for the NOR memory strings in multiple planes.

Fourth, in embodiments of the present invention, the memory structure can be constructed using air gaps as the insulation between the active layers forming the NOR memory strings in the vertical direction. Air gaps have a dielectric constant approximately 1.0, which is considerably lower than most dielectric materials, thereby effectively reducing the parasitic capacitance between adjacent pair of NOR memory strings in the vertical direction. Using air gaps as the isolation between active layers improve the isolation between adjacent NOR memory string and enhance the performance of the memory device formed therefrom. In some embodiment, the inter-layer isolation layer between active layers includes an air gap liner layer to passivate the exposed surfaces of the inter-layer cavities, the remaining unfilled portions of the cavities forming the air gap isolation.

Fifth, in embodiments of the present invention, each storage transistor in the stacks of NOR memory strings may be isolated from other storage transistors in both the horizontal and vertical directions. In particular, each NOR memory string in a stack is isolated from other NOR memory strings in the same stack by the inter-layer isolation layer, which can be an air gap isolation. The storage transistors in each NOR memory string are further separated and isolated from each other along the NOR memory string (in the horizontal direction). For example, the channel layer between adjacent columns of the gate conductor layer formed in the narrow trenches is removed to isolate the storage transistors along the NOR memory strings in the horizontal direction. In this manner, each storage transistor can be completely isolated from other storage transistors in the same NOR memory string or from storage transistors in NOR memory strings formed in other planes in the same stack. The storage transistors in each NOR memory string are controlled by individual gate conductors to allow each storage transistor to be individually addressed and accessed.

These and other advantages of the memory structure of the present invention will be described further in the following description. In the present description, to facilitate reference to the figures, a Cartesian coordinate reference frame is used, in which the Z-direction is normal to the planar surface of the semiconductor surface and the X-direction and the Y-directions are orthogonal to the Z-direction and to each other, as indicated in the figures. Furthermore, the drawings provided herein are idealized representations to illustrate embodiments of the present disclosure and are not meant to be actual views of any particular component, structure, or device. The drawings are not to scale, and the sizes and relative sizes and dimensions of layers and regions may be exaggerated for clarity. Variations from the shapes of the illustrations are to be expected. For example, a region illustrated as a box shape may typically have rough and/or nonlinear features. Sharp angles that are illustrated may be rounded. Like numerals refer to like components throughout.

In the present description, the term “storage transistor” is used interchangeably with “memory transistor” to refer to the memory device formed in the memory structure described herein. In some examples, the memory structure of the present disclosure including NOR memory strings of randomly accessible storage transistors (or memory transistors) can have applications in computing systems as the main memory where the memory locations are directly accessible by the processors of the computer systems, for instance, in a role served in the prior art by conventional random-access memories (RAMs), such as dynamic RAMs (DRAMS) and static RAMs (SRAMs). For example, the memory structure of the present disclosure can be applied in computing systems to function as a random-access memory to support the operations of microprocessors, graphical processors and artificial intelligence processors. In other examples, the memory structure of the present disclosure is also applicable to form a storage system, such as a solid-state drive or replacing a hard drive, for providing long term data storage in computing systems.

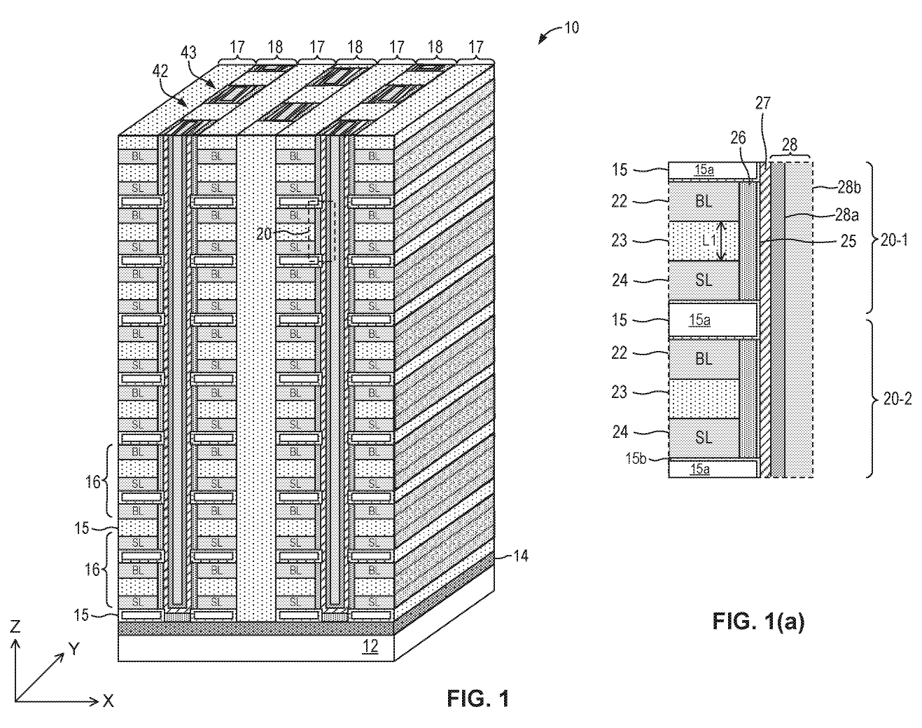

FIG. 1, which includes FIG. 1(a), is a perspective view of a memory structure including a 3-dimensional array of NOR memory strings in some embodiments. The memory structure can be used to implemented part of a semiconductor memory device in some examples. Referring to FIG. 1, a memory structure 10 includes a number of active layers 16 formed on a planar surface of a semiconductor substrate 12. An insulating layer 14 may be provided between the semiconductor substrate 12 and the active layers 16 formed on the substrate. The active layers 16 are formed one on top of another in the Z-direction (i.e., along a direction normal to the planar surface of the substrate 12) and separated from each other by an inter-layer isolation layer 15. The active layers 16 are divided in the X-direction into narrow strips (“active strips”) that are stacked one on top of another to form stacks of active strips 17 (“active stacks 17”) extending in the Y-direction. The stacks 17 are also referred to as memory stacks in the present description.

Each active layer 16 includes first and second low resistivity conductive layer (e.g., titanium nitride (TiN)-lined tungsten (W)), separated by a channel spacer dielectric layer (e.g., silicon oxide). During intermediate processing steps, the active layer may include sacrificial layers (e.g., silicon nitride) to be subsequently replaced by conductive layers. Subsequent processing steps form the channel layers, the gate dielectric layers, and the gate conductor layers in narrow trenches 18 between the separated active stacks. The narrow trenches 18 are also referred to as “LWL trenches” in the present description. The gate conductor layers and the gate dielectric layers are formed as columnar structures extending in the Z-direction. In the present description, the gate conductor layers are also referred to as “local word lines” and a gate conductor with a gate dielectric layer is collectively referred to a local word line (LWL) structure 43. The local word line structures 43 in each trench 18 are separated from each other by a dielectric-filled shaft 42.

The first and second conductive layers of each active strip form a drain region (“common bit line”) and a source region (“common source line”), respectively, of the storage transistors. The storage transistors may be formed along one or both sides of the active strip in an active stack 17. In particular, a storage transistor 20 is formed at the intersection of an active strip with the channel layer and an LWL structure 43. In the present illustration, the LWL structures 43 are formed staggered in adjacent trenches bordering an active strip so that storage transistors formed on both sides of an active strip are offset from each other in the Y-direction along the memory string.

In the present embodiments, the storage transistors are ferroelectric storage transistors and the gate dielectric layer is a ferroelectric gate dielectric layer. In some embodiments, the ferroelectric gate dielectric layer is formed of a doped hafnium oxide material, such as zirconium-doped hafnium oxide (HfZrO or “HZO”). In other embodiments, the hafnium oxide can be doped with silicon (Si), iridium (Ir) or lanthanum (La). In some embodiments, the ferroelectric gate dielectric layer is a material selected from: zirconium-doped hafnium oxide (HZO), silicon-doped hafnium oxide (HSO), aluminum zirconium-doped hafnium oxide (HfZrAlO), aluminum-doped hafnium oxide (HfO₂:Al), lanthanum-doped hafnium oxide (HfO₂:La), hafnium zirconium oxynitride (HfZrON), hafnium zirconium aluminum oxide (HfZrAlO), and any hafnium oxide that includes zirconium impurities.

FIG. 1(a) illustrates the detail construction of the storage transistor 20 formed in the memory structure 10 in some embodiments. In particular, FIG. 1(a) illustrates a pair of storage transistors 20-1 and 20-2 in two adjacent planes of a memory stack. Referring to FIG. 1(a), the storage transistor 20 includes a first conductive layer 22 forming the drain region (the common drain line or the common bit line) and a second conductive layer 24 forming the source region (the common source line), the conductive layers being spaced apart by the channel spacer dielectric layer 23. The storage transistor 20 further includes the channel layer 26 formed vertically along the sidewall of the memory stack and in contact with both the first conductive layer 22 and the second conductive layer 24. The gate dielectric layer 27 and the gate conductor layer 28 are formed on the sidewall of the memory stack. The storage transistor 20 is isolated from adjacent storage transistors in the stack by an inter-layer isolation layer 15. As thus configured, along each active strip (in the Y-direction), the storage transistors that share the common source line and the common bit line form a NOR memory string (referred herein as a “Horizontal NOR memory string” or “HNOR memory string”).

Each storage transistor 20 is isolated from adjacent storage transistors along an active stack (in the Z-direction) by the inter-layer isolation layer 15. In the present embodiment, the inter-layer isolation layer 15 is an air gap isolation formed by an air gap cavity 15a and an optional air gap liner 15b. The air gap liner 15b is a dielectric layer used to passivate the exposed surface of the air gap cavity 15a. In one embodiment, the air gap liner 15b is a silicon nitride layer. The air gap liner 15b may be 1nm-3nm thick. In FIG. 1(a), elements are sometimes exaggerated in size for illustrative purposes only. It is understood that the depictions in this and other figures are not necessarily to scale. The air gap cavities 15a forming the inter-layer isolation layer 15 provides effective isolation between adjacent storage transistors 20 along a memory stack. In embodiments of the present invention, the inter-layer isolation layer 15 is also used to provide physical separation between the channel layer 26 of one storage transistor and the channel layer of the storage transistors above or below it in the same memory stack, as will be described in more details below.

In embodiments of the present invention, the storage transistors in the memory structure 10 are junctionless ferroelectric storage transistors. Accordingly, each storage transistor 20 includes only conductive layers as the source and drain regions, without any semiconductor layers. The first and second conductive layers are formed using a low resistivity metallic conductive material. In some embodiments, the first and second conductive layers are metal layers, such as a titanium nitride (TiN)-lined tungsten (W) layer, a tungsten nitride (WN)-lined tungsten (W) layer, a molybdenum nitride (MoN) lined molybdenum (Mo) layer, or a liner-less tungsten or molybdenum or cobalt layer, or other metal layers. The channel spacer dielectric layer 23 between the first and second conductive layers may be a dielectric layer, such as silicon dioxide (SiO₂). The channel layer 26 is a semiconductor oxide layer. In some examples, the channel layer 26 is formed using an amorphous oxide semiconductor material, such as indium gallium zinc oxide (InGaZnO or IGZO), indium zinc oxide (IZO), indium tungsten oxide (IWO), or indium tin oxide (ITO), or other such semiconductor oxide materials. A semiconductor oxide channel region has the advantage of a high mobility for greater switching performance and without concern for electron or hole tunneling. For example, an IGZO film has an electron mobility of 10.0-100.0 cm²/V, depending on the relative compositions of indium, gallium, zinc and oxygen.

In the present example, the gate conductor layer 28 includes a titanium or titanium nitride layer 28a bordering the gate dielectric layer 27 and a conductive filler layer 28b, such as tungsten or a heavily doped polysilicon layer, filling the remaining area in the local word line.

To form the ferroelectric storage transistor, the gate dielectric layer 27 of the storage transistor 20 is a ferroelectric gate dielectric layer or ferroelectric polarization layer 27 in contact with the channel layer 26. The ferroelectric polarization layer 27 serves as the storage layer of the storage transistor. In some embodiments, an interfacial layer 25 may be provided between the semiconductor oxide channel layer 26 and the ferroelectric polarization layer 27. The interfacial layer 25 is a thin layer and may be 0.5nm to 2nm thick. In some embodiments, the interfacial layer is formed using a material with a high dielectric constant (K) (also referred to as “high-K” material). In the present description, a material with a high dielectric constant or a high-K material refers to a material with a dielectric constant greater than the dielectric constant of silicon dioxide. In some embodiments, the interfacial layer 25 may be a silicon nitride (Si₃N₄) layer, or a silicon oxynitride layer, or an aluminum oxide (Al₂O₃) layer. In one example, the interfacial layer, if present, may have a thickness of 1.5nm when the ferroelectric polarization layer has a thickness of 4-5nm. The inclusion of the interfacial layer 25 in FIG. 1(a) is illustrative only and not intended to be limiting. The interfacial layer 25 is optional and may be omitted in other embodiments of the present invention. In other embodiments, the interfacial layer 25, when included, may be formed as a multi-layer of different dielectric materials.

A salient feature of the ferroelectric storage transistor 20 is that the storage transistor can have a very short channel length, which is operative to increase the voltage separation between the different threshold voltages, while the memory structure 10 can be manufactured without requiring costly lithography techniques to realize the short channel length. In particular, the channel length of the ferroelectric storage transistor 20 is determined by the thickness L1 of the channel spacer dielectric layer 23. The thickness L1 can be accurately controlled during the deposition of the sublayers 22, 23, 24 forming the initial memory stack. The ability to control the thickness L1 by deposition process, together with the very low channel leakage of semiconductor oxide channel layer, make it possible to provide a ferroelectric storage transistor 20 with very short channel length, such as a channel length of 5nm, without needing to employ costly lithography such as extreme ultraviolet scanners (EUV) that are necessary to pattern short channels in planar transistors. In some embodiments, the thickness L1, or the channel length of the storage transistor, can be between 5nm and 20nm, or between 5-7nm.

Referring again to FIG. 1, to complete the memory circuit, various types of circuitry are formed in or at the surface of the semiconductor substrate 12 to support the operations of the HNOR memory strings. Such circuits are referred to as “circuits under array” (“CuA”) and may include digital and analog circuitry such as decoders, drivers, sense amplifiers, sequencers, state machines, exclusive OR circuits, memory caches, multiplexers, voltage level shifters, voltage sources, latches and registers, and connectors, that execute repetitive local operations such as processing random address, activate, erase, program, read, and refresh commands with the memory arrays formed above the semiconductor substrate 12. In some embodiments, the transistors in the CuA is built using a process optimized for the control circuits, such as an advanced manufacturing process that is optimized for forming low-voltage and faster logic circuits. In some embodiments, the CuA is built using fin field-effect transistors (FinFET) or gate-all-around field-effect transistors (GAAFET) to realize a compact circuit layer and enhanced transistor performance.

In some embodiments, the CuA provides the data path to and from the memory array and further to a memory controller that may be built on the same semiconductor substrate as the CuA. Alternatively, the memory controller may reside on a separate semiconductor substrate, in which case the CuA and the associated data path are electrically connected to the memory controller using various bonding techniques. In some examples, the memory controller includes control circuits for accessing and operating the storage transistors in the memory array connected thereto, performing other memory control functions, such as data routing and error correction, and providing interface functions with systems interacting with the memory array.

The memory structure 10 of FIG. 1 illustrates a construction of a 3-dimensional array of NOR memory strings in some embodiments. In some embodiments, the memory structure 10 is fabricated in process that realizes advantageous features for the memory structure. First, the memory structure 10 is formed so that the storage transistors in the 3-dimensional array of NOR memory strings are individually isolated from other storage transistors. In particular each storage transistor is isolated in the vertical direction by the inter-layer isolation layer and in the horizontal direction by isolating the channel layer to each local word line structure 43, as shown in FIG. 1. The performance characteristics of the storage transistors are enhanced by individually isolating each storage transistors. Second, the channel layer can be deposited conformally and then channel separation between active layers in the memory stacks is realized by etching through access openings formed by the inter-layer sacrificial layer. This results in a simplified and more reliable process for forming the channel layer. Third, after the removal of the inter-layer sacrificial layer for channel separation, the remaining cavities between active layers can form air gap isolation between the active layers, realizing better isolation than most dielectric materials.

The memory structure 10 of the present disclosure includes a memory array portion fabricated as described above to form the 3-dimensional array of NOR memory strings. To complete the memory device, the memory structure includes staircase portions provided at the ends of the memory strings (in the Y-directions). The staircase portions are not shown in the present figures to simplify the discussion. The thin-film storage transistors of the NOR memory strings are formed in the memory array portion while the staircase portions include staircase structures to provide connections through conductive vias to the common bit lines and, optionally, the common source lines, of the NOR memory strings. In some embodiments, the common source lines are pre-charged to serve as virtual voltage reference source during programming, reading and erase operations, thereby obviating the need for a continuous electrical connection with the support circuitry during such operations. In the present description, the common source lines are described as being electrically floating. Various processing steps for forming staircase structures in the memory structure can be used. The processing steps for forming the staircase structures can be before, after, or interleaved with the processing steps for forming the memory array portion described below.

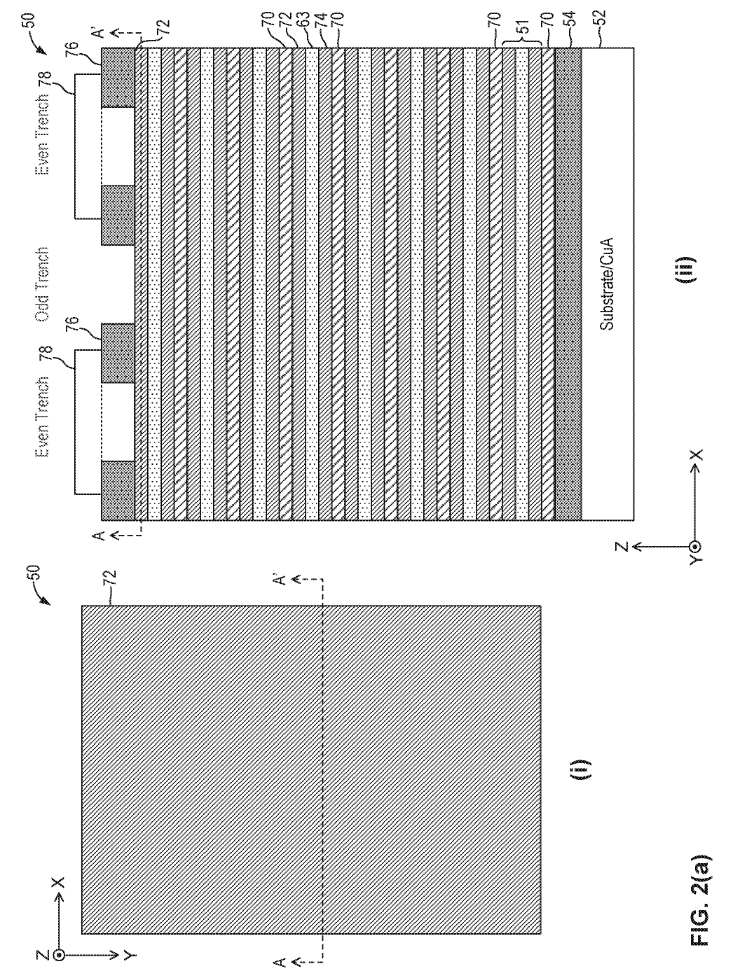

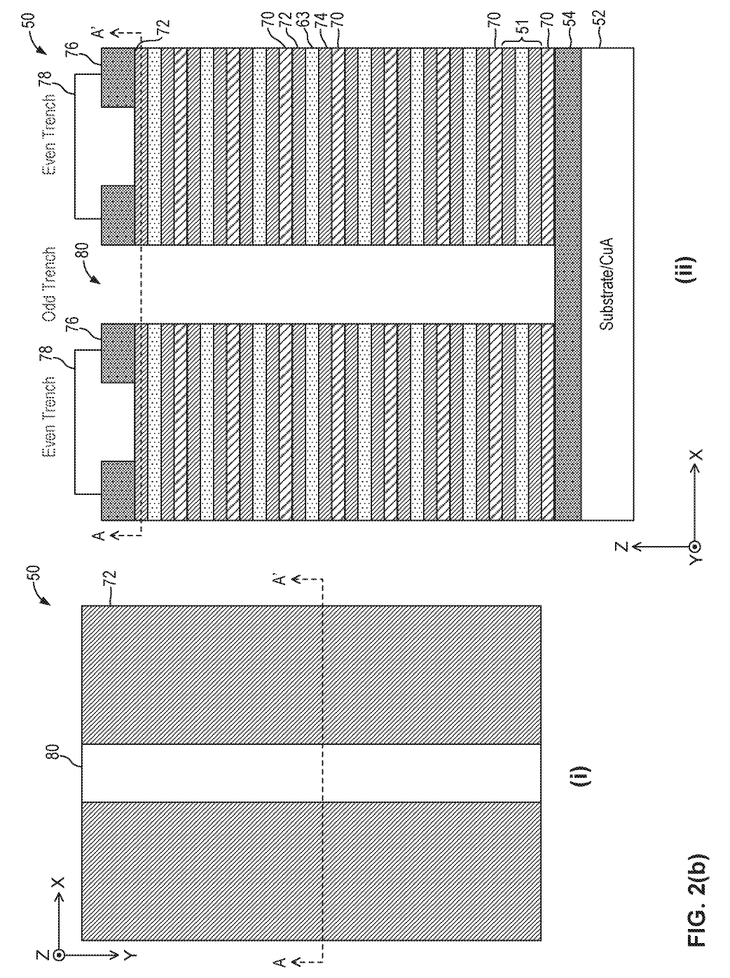

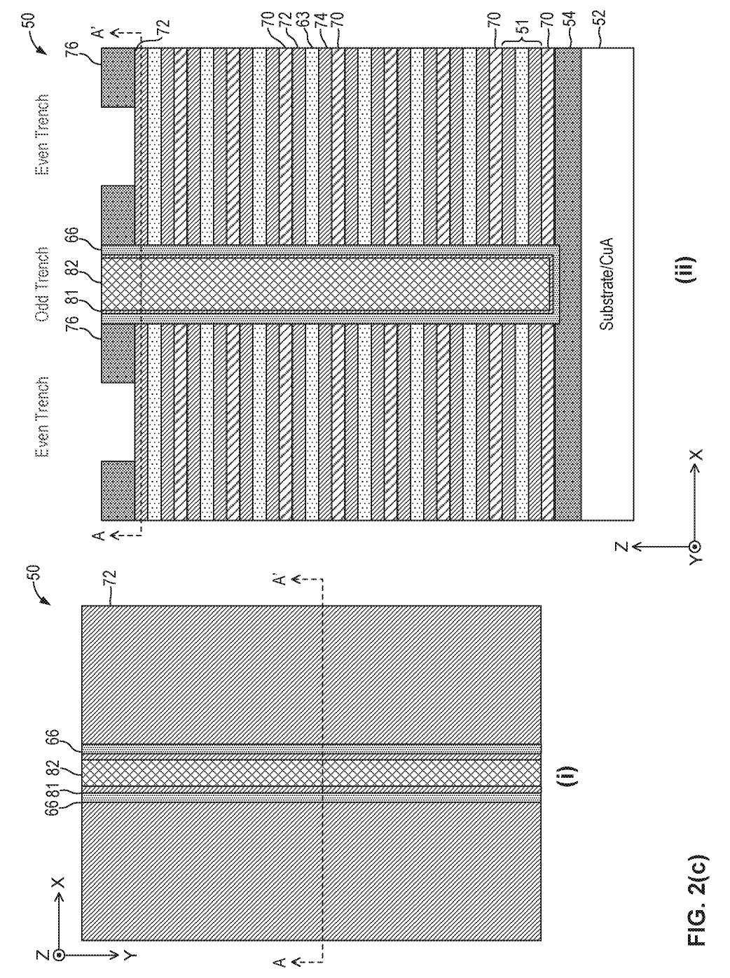

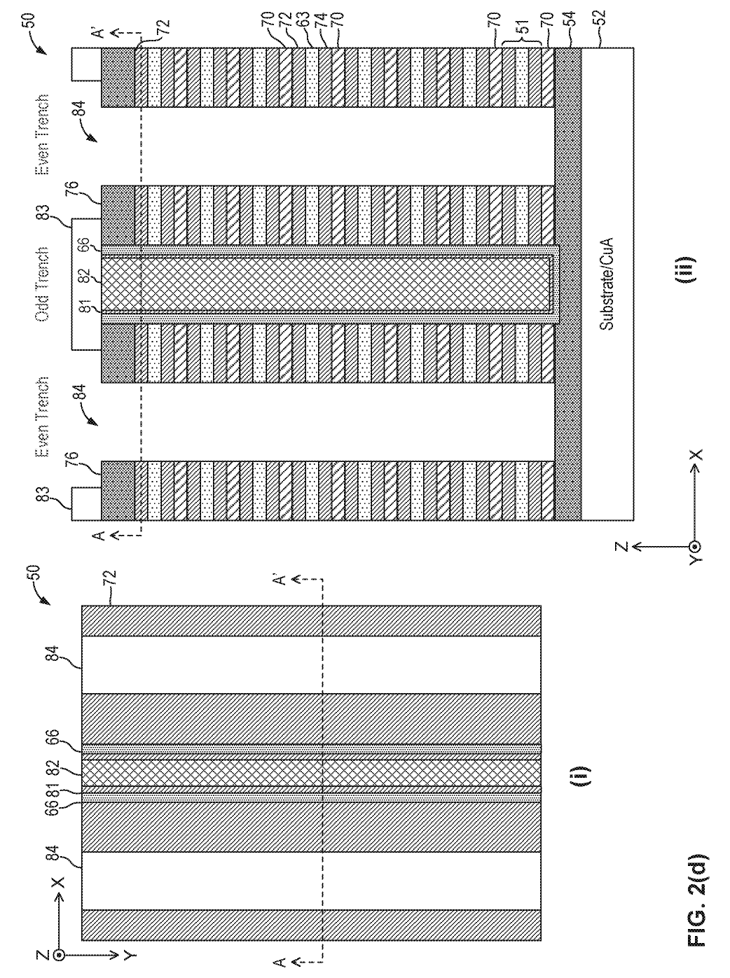

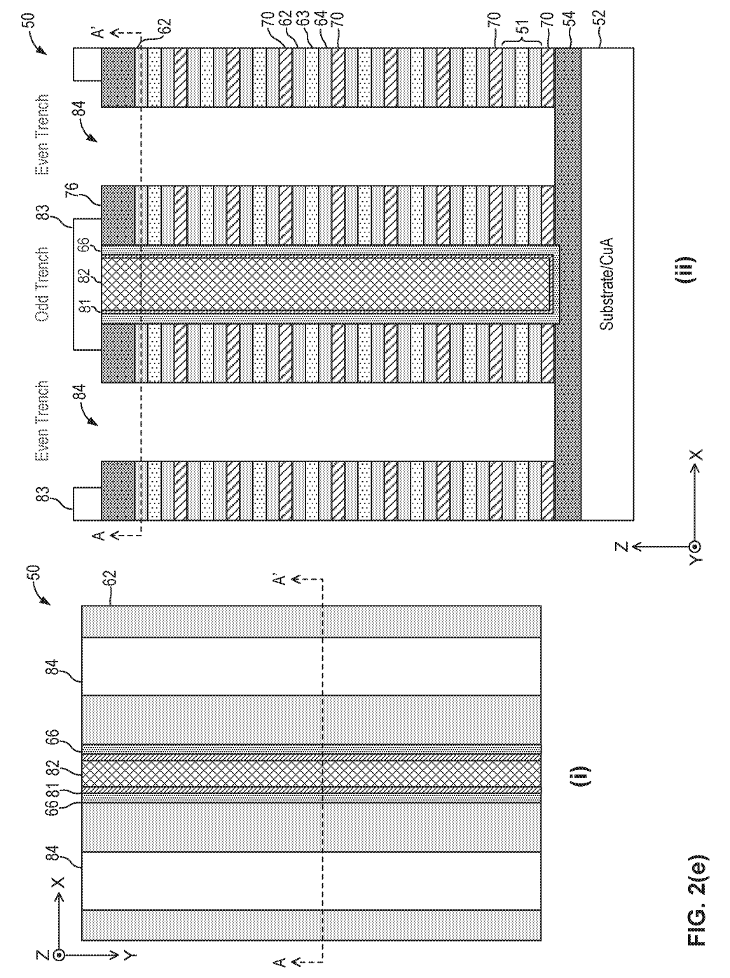

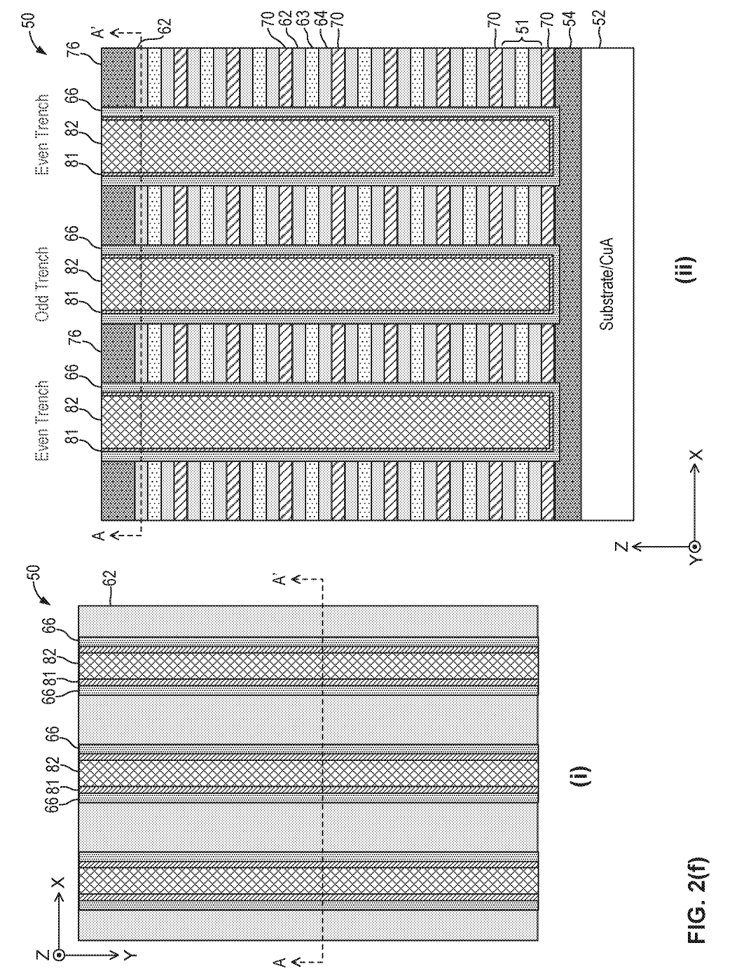

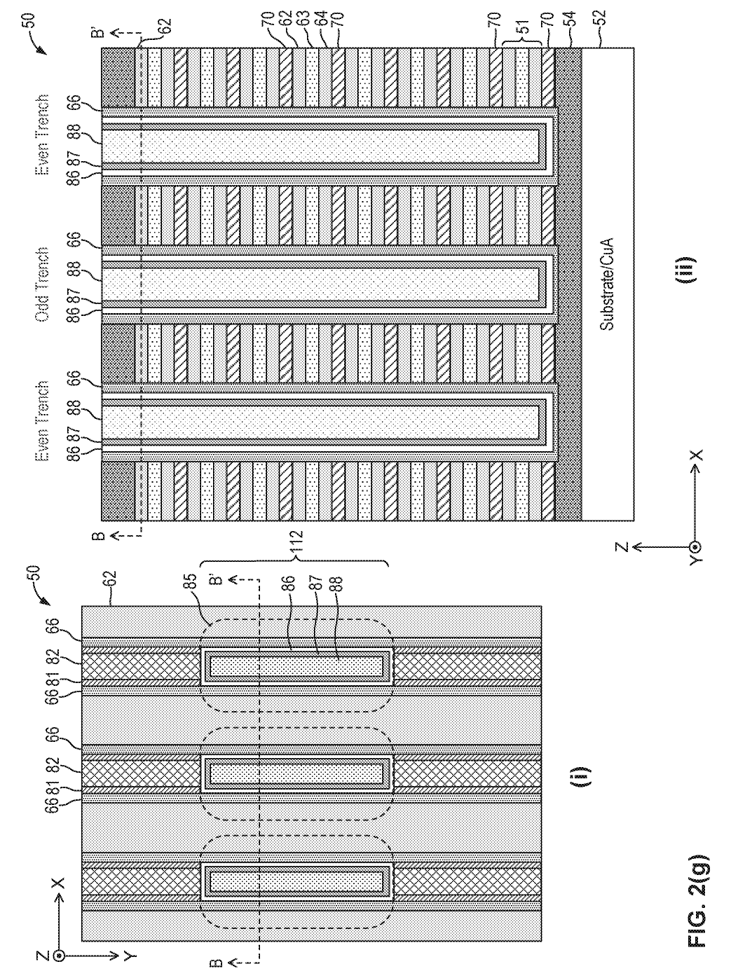

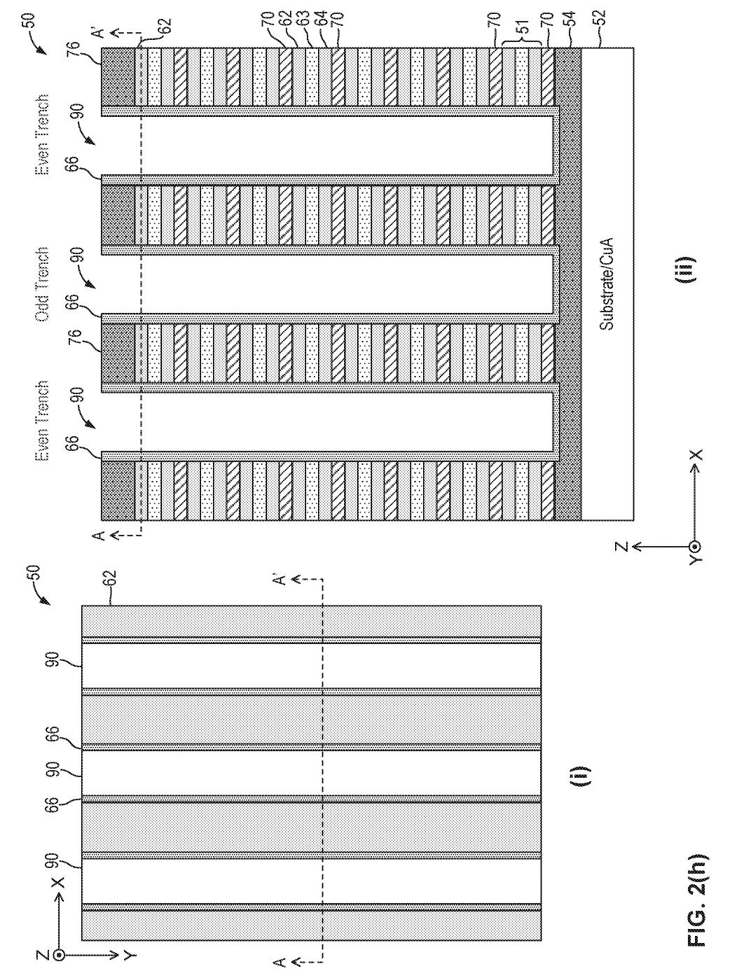

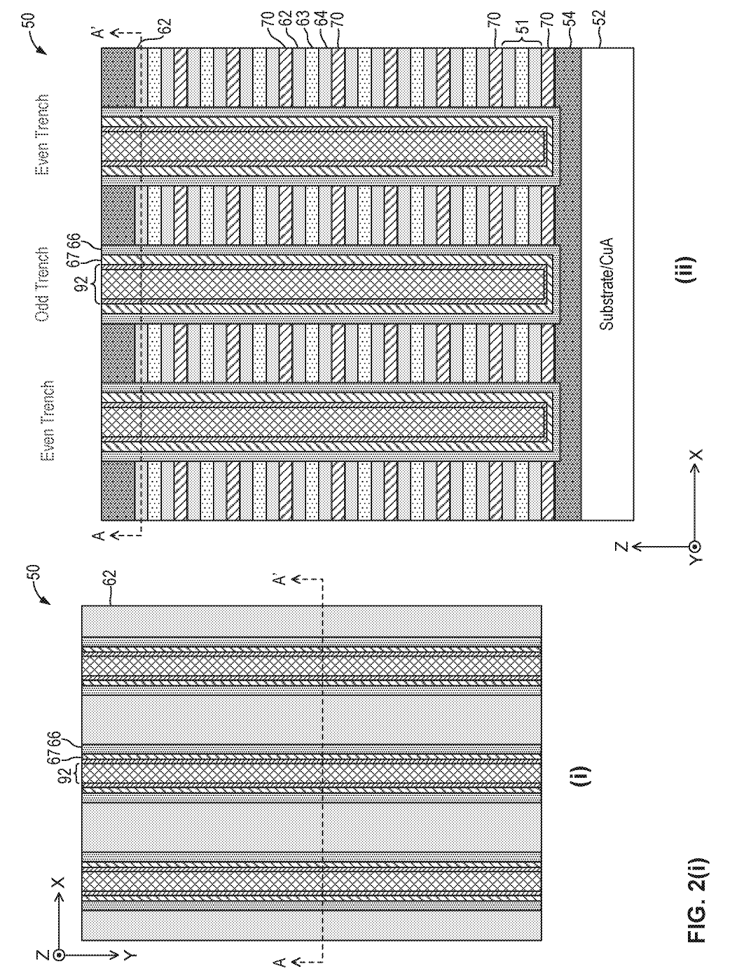

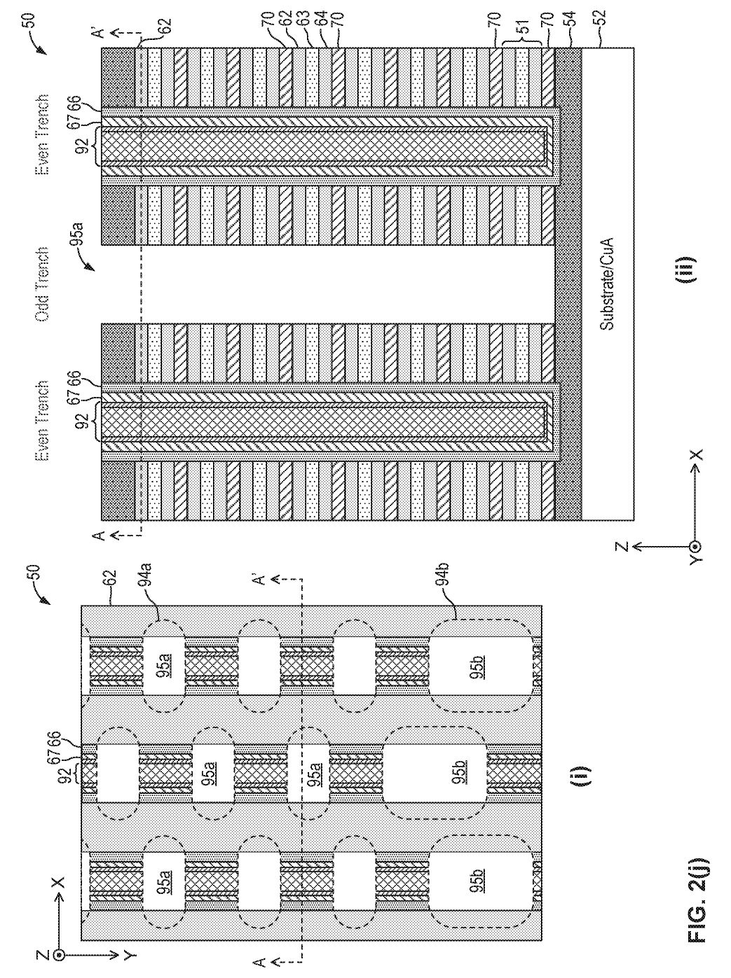

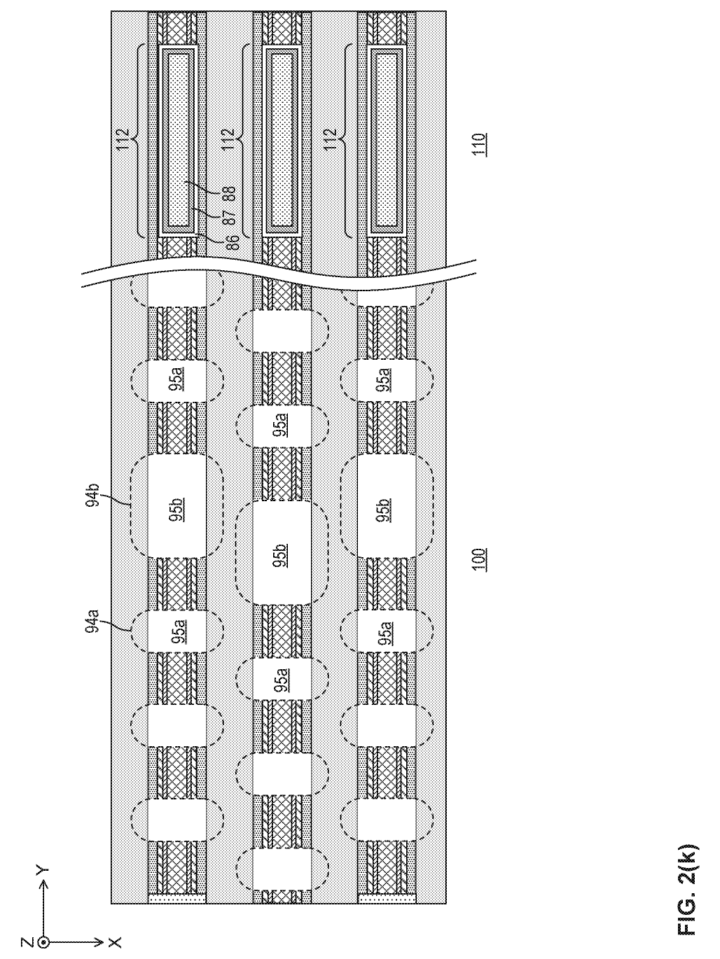

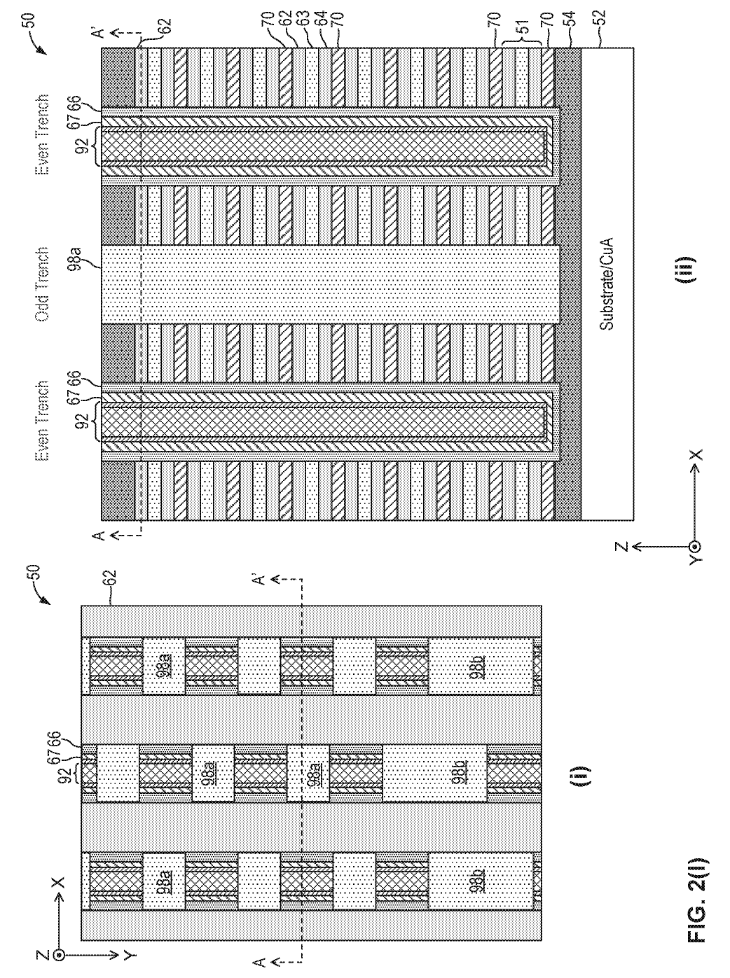

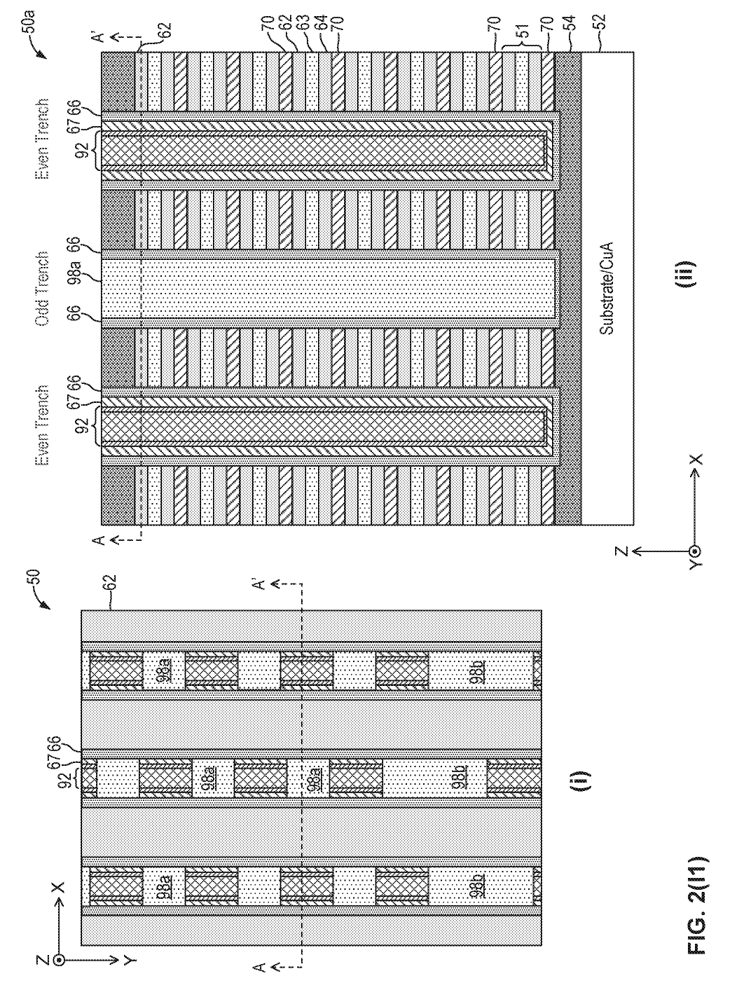

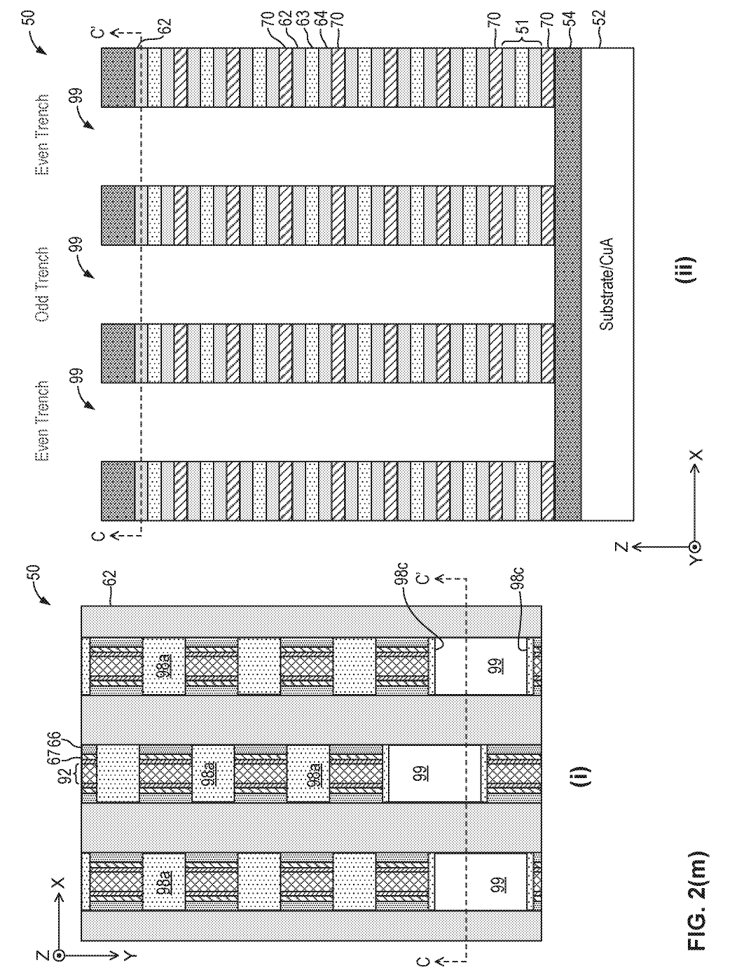

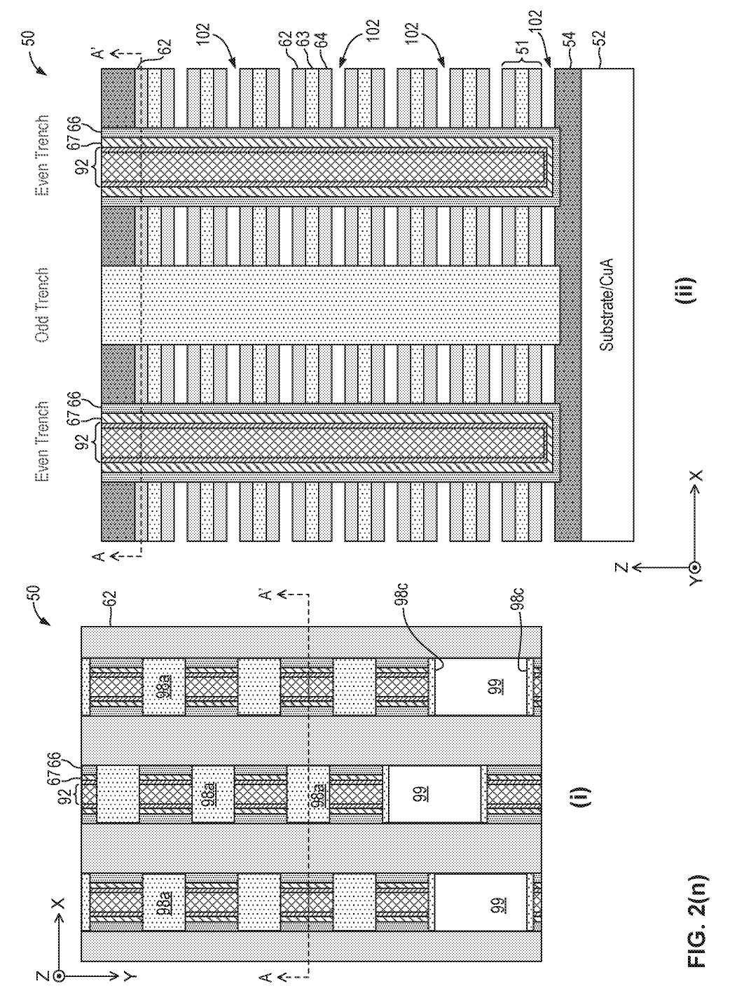

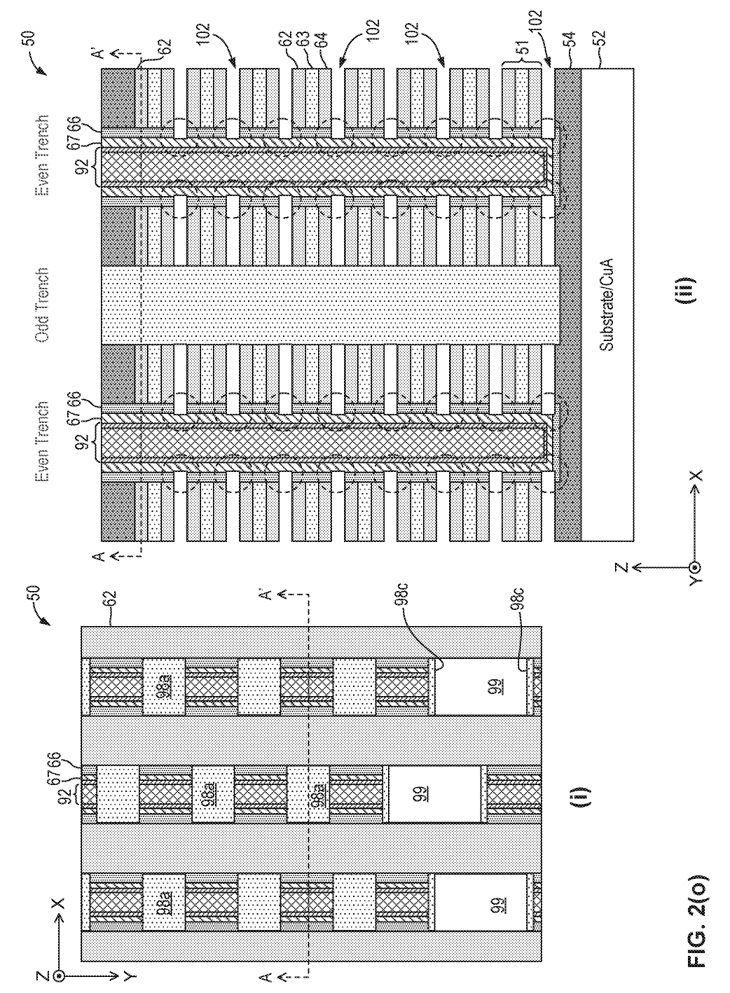

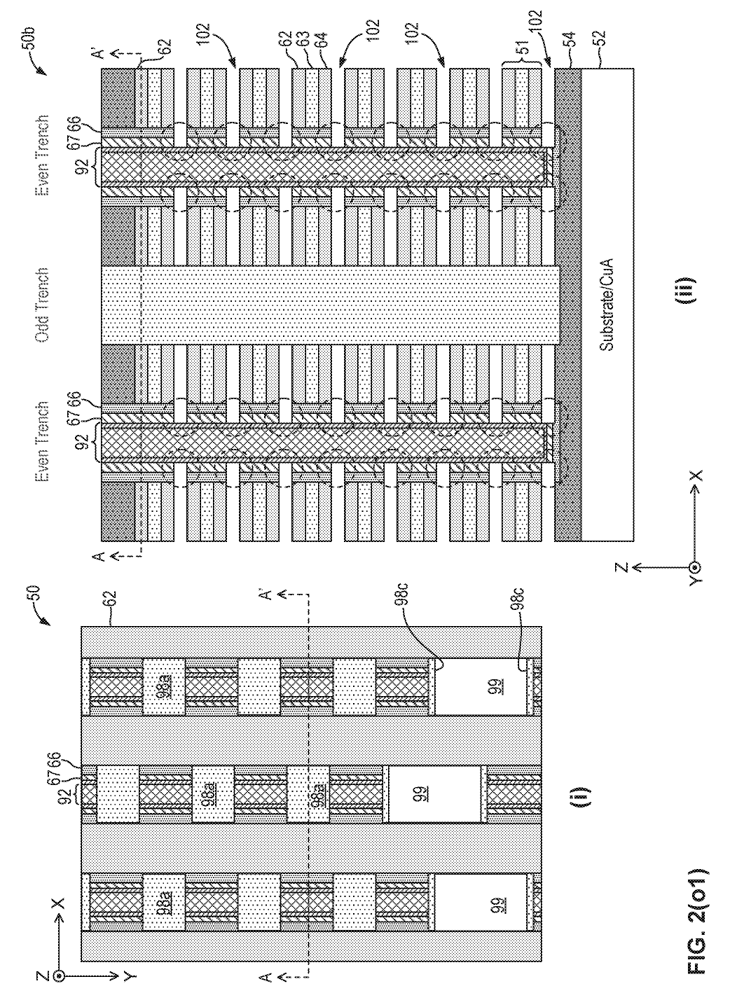

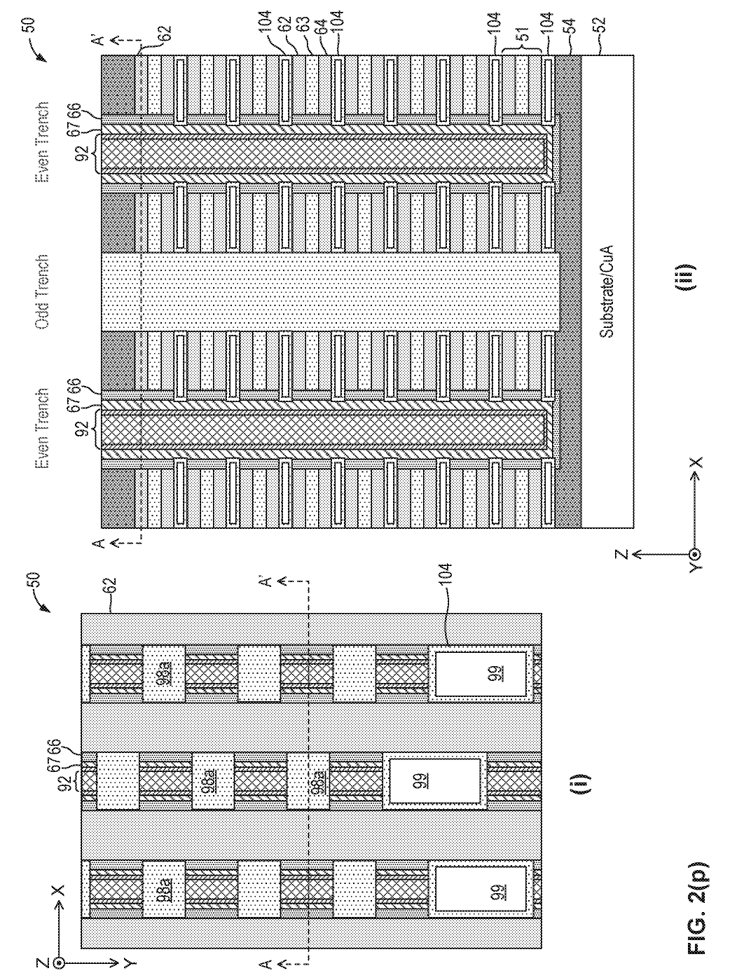

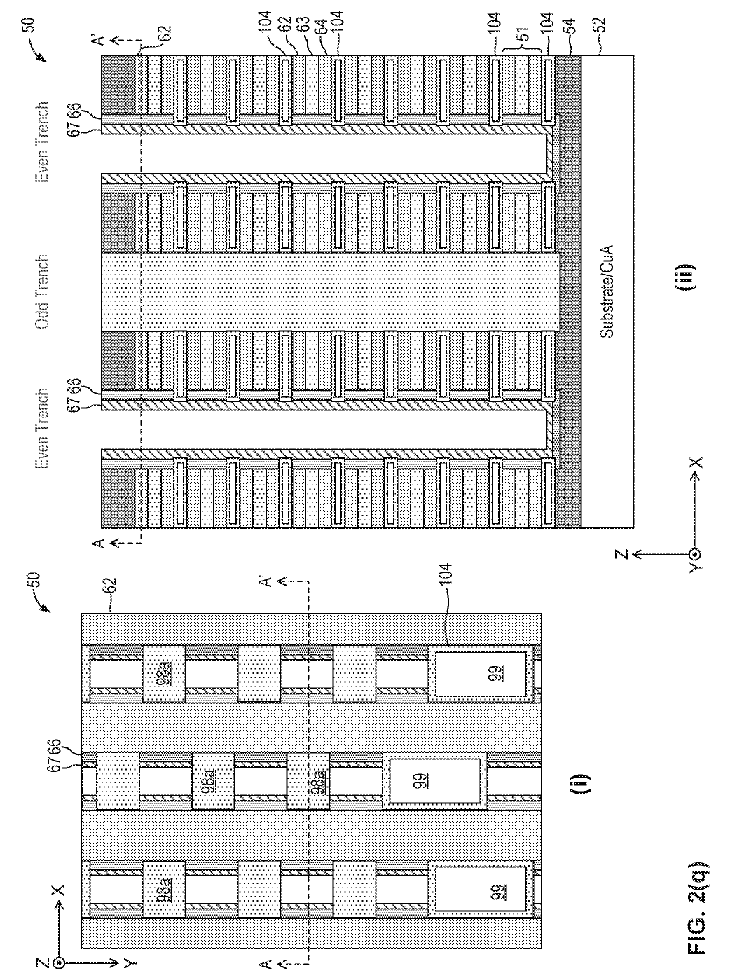

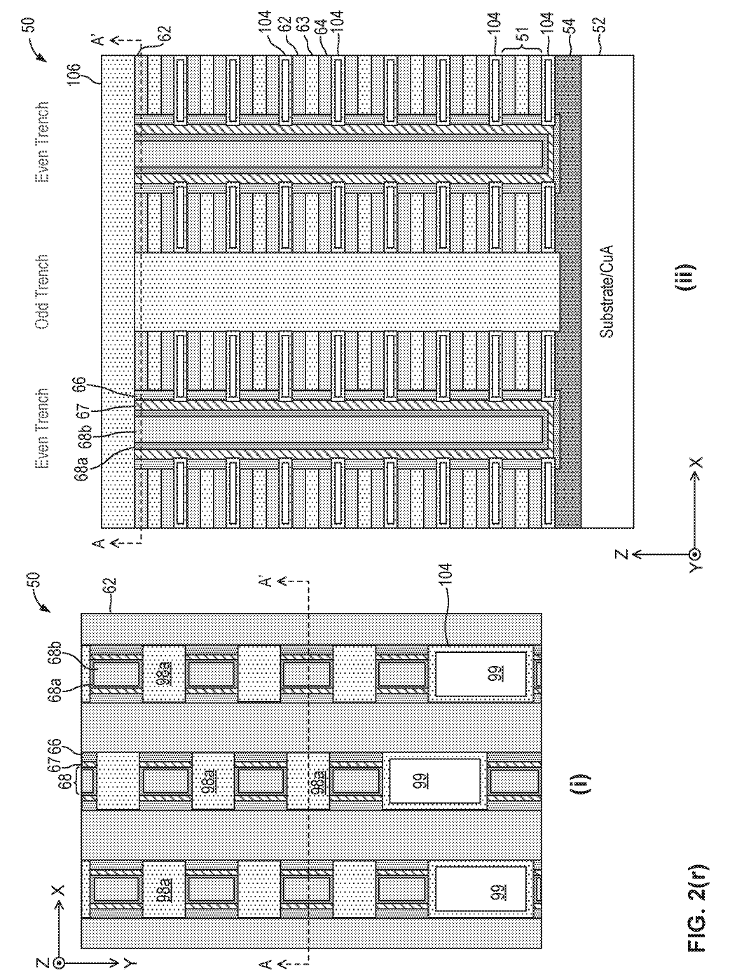

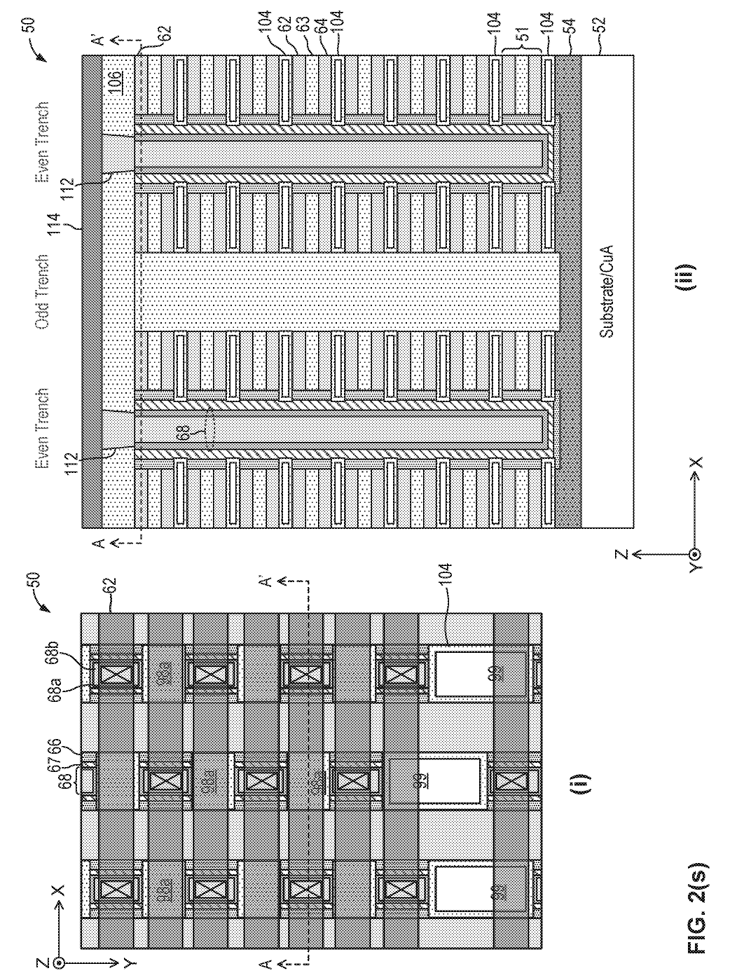

FIGS. 2 (a) - 2 (s) , including 2 (l 1 ) and 2 (o 1 ) , illustrate a process for fabricating a memory structure including HNOR memory strings in embodiments of the present invention. Each figure in FIGS. 2 (a) - 2 (j) , and 2 (l) - 2 (s) includes two views: view (i) is a horizontal cross-sectional view (i.e., in an X-Y plane) along A-A’, B-B’, or C-C’ in view (ii), and view (ii) is a vertical cross-sectional view (i.e., in an X-Z plane) along line A-A’, B-B’, or C-C’ in view (i).

Referring to FIG. 2(a), initially, a semiconductor substrate 52 is provided and any circuitry to be formed in the substrate 52, such as the CuA and the interconnect conductors, are fabricated in or on the substrate 52. An insulating layer 54 is provided on top of the semiconductor substrate to cover and protect the circuitry formed on and in the semiconductor substrate 52. In some embodiments, the insulating layer 54 is a dielectric layer which may also serve as an etch stop layer for the subsequent processing steps. In some embodiments, the insulating layer 54 is a silicon oxycarbide (SiOC) layer or an aluminum oxide (Al₂O₃) layer. The insulating layer 54 can be formed using any material with suitable selectivity for the subsequent etch processes to be performed.

Subsequently, a memory structure 50 is formed by successive depositions of (i) a multilayer 51 and (ii) an inter-layer sacrificial layer 70 on the planar surface of a semiconductor substrate 52, or in particular, on the insulating layer 54. The multilayer 51 includes three sublayers: (a) a first sacrificial layer 72, (b) a channel spacer dielectric layer 63, and (c) a second sacrificial layer 74, in this order in the Z-direction. FIG. 2(a) shows the memory structure 50 after the depositions of the initial layers of thin films. Multilayer 51 is also referred to in this detailed description as an “active layer.” View (i) in FIG. 2(a) illustrates the horizontal cross-section along a line A-A’ in the first sacrificial layer 72 in view (ii). View (ii) in FIG. 2(a) illustrates the vertical cross-section of the memory structure 50 along the line A-A’ shown in view (i). The first and second sacrificial layers 72 and 74 are to be replaced by respective conductive layers in subsequent processing. The inter-layer sacrificial layer 70 (also referred herein as the third sacrificial layer) is to be replaced by an isolation material in subsequent processing to form an inter-layer isolation layer.

In the present embodiment, the first and second sacrificial layers 72 and 74 are each a silicon nitride layer. The channel spacer dielectric layer 63 is an insulating dielectric material, such as silicon oxide (SiO₂). The third sacrificial layer 70 is a sacrificial layer selected from carbon, amorphous silicon (aSi), and silicon germanium (SiGe).

In one embodiment, each sublayer in the multilayer 51 and the inter-layer sacrificial layer 70 has a thickness of typically 30nm or less. In another embodiment, the sublayers in the multilayer 51 and the inter-layer sacrificial layer 70 do not have the same thickness. In the present description, the dimensions are provided merely for illustrative purposes and are not intended to be limiting. In actual implementation, any suitable thicknesses or dimensions may be used. In some embodiments, the lowermost and uppermost sublayers (70 and 72 respectively in the example of FIG. 2(a)) of memory stack 50 may optionally be designated as dummy sublayers that are not necessarily part of an active layer.

After the memory structure is formed with the desired number of multi-layers with the third sacrificial layers therebetween, a hard mask 76 is formed on the top of the memory structure. In one embodiment, the hard mask 76 is a silicon oxycarbide layer (SiOC). The hard mask is patterned to define trenches in which storage transistors are to be formed, for example, using a photo-lithographical patterning step. In particular, the hard mask defines a set of even trenches and a set of odd trenches. In one example, the trenches have a width of 60nm and a pitch of 100 nm. After the hard mask 76 is patterned, a second mask 78 is formed over the hard mask 76 which covers exposed areas in the hard mask 76 corresponding to the even trenches. The processing that follows will be performed first in the areas associated with the odd trenches exposed by the second mask 78. Processing in the areas associated the even trenches will be performed in a later stage when the second mask 78 is removed. In some embodiments, the second mask 76 maybe planarized to the surface of the hard mask 76, as shown by the dotted line in FIG. 2(a).

Referring to FIG. 2(b), a first set of trenches 80 are formed in memory structure 50 using, for example, a selective anisotropic etch process with the hard mask 76 and the second mask 78 as the masking layer. The first set of trenches 80 is referred to as the odd trenches. In some examples, the trenches 80 may be 60 nm wide, with a spacing of 160 nm apart, that is, the mesa formed between two adjacent trenches is 160nm. Subsequently, referring to FIG. 2(c), a channel layer 66 is deposited conformally on the sidewall of the trenches 80. In one embodiment, the channel layer 66 is deposited by atomic layer deposition (ALD), chemical vapor deposition (CVD) or a combination thereof. In the present embodiment, the channel layer 66 is a semiconductor oxide layer, such as indium gallium zinc oxide (IGZO), indium zinc oxide (IZO), indium tungsten oxide (IWO), or indium tin oxide (ITO). In other examples, the channel layer 66 can be formed using other oxide semiconductor material compatible with IGZO. Furthermore, in some embodiments, the channel layer 66 may have a thickness of 1.5nm to 10nm. A liner layer 81 is deposited to cover the channel layer 66 and the remaining volume in the trenches 80 is filled with a sacrificial material 82. In one embodiment, the liner layer 81 can be a low temperature (under 500ºC) silicon nitride layer and have a thickness of 3nm. Alternately, the liner layer 81 can be an undoped amorphous silicon layer. In some embodiments, the sacrificial material 82 can be one of silicon germanium, phosphosilicate glass (PSG) or borophosphosilicate glass (BPSG) or silicon oxide. In one embodiment, the sacrificial material 82 is silicon germanium or carbon. To best protect the channel layer 66, the liner layer 81 is preferably deposited in the same deposition tool to avoid exposure of the channel layer to oxidation. After the deposition steps, excess material may be removed from the top of memory structure 50 using, for example, chemical-mechanical polishing (CMP). The second mask 78 is removed with the hard mask 76 remaining. The resulting memory structure 50 is shown in FIG. 2(c).

Referring to FIG. 2(d), a third mask 83 is applied and patterned to cover the odd trenches while exposing openings where the even trenches are defined by the hark mask 76. With the mechanical support from the sacrificial material 82, a second set of trenches 84 are then formed using substantially the same technique as discussed in conjunction with FIG. 2(b) above. For example, the memory structure is selective anisotropically etched with the hard mask 76 and the third mask 83 as the masking layer. The second set of trenches 84 is referred to as the even trenches. In some examples, the trenches 84 may be 60 nm wide. Each of the second set of trenches 84 is cut between an adjacent pair of the first set of trenches 80 and each of the second set of trenches 84 is cut substantially equidistant between an adjacent pair of the first set of trenches 80. As a result of trenches 80 and 84 being cut in the multilayer structure, stacks in the multilayer structure are formed which are referred to as “active stacks” in the present description. In some examples, the active stacks are each approximately 40 nm wide. The resulting narrow strips in each plane resulting from the cutting of the active layers 51 are referred herein as “active strips.”

Thereafter, first and second sacrificial layers 72 and 74 are removed using, for example, a selective wet etch, thereby creating cavities between the channel spacer dielectric layer 63 and the inter-layer sacrificial layer 70. The cavities are filled by first and second conductive layers 62 and 64, as shown in FIG. 2(e). The interface between conductive layers 62, 64 and the channel layer 66 should be cleaned of any surface oxidation while protecting the channel layer from damage. In some embodiments, the first and second conductive layers 62, 64 are formed using a low resistivity metallic conductive material. In some embodiments, the first and second conductive layers are metal layers, such as a titanium nitride (TiN)-lined tungsten (W) layer, a tungsten nitride (WN)-lined tungsten (W) layer, a molybdenum nitride (MoN) lined molybdenum (Mo) layer, or a liner-less tungsten or molybdenum or cobalt layer, or other metal layers. In one example, the first and second conductive layers 62 and 64 are each formed by successively depositing a titanium nitride (TiN) liner and a tungsten (W) layer. The TiN liner may be formed using, for example, an atomic layer deposition (ALD) technique and the tungsten layer may be formed using, for example, CVD or PECVD techniques. An etching step removes the deposited material from the sidewalls of trenches 84. In some examples, an isotropic wet etch is used to remove the deposited material from the sidewalls of trenches 84. The resulting memory structure 50 is shown in FIG. 2(e). The third mask 83 is then removed.

Subsequently, referring to FIG. 2(f), a channel layer 66 is deposited conformally on the sidewall of trenches 84, in the same manner as described above with reference to FIG. 2(c). For example, the channel layer 66 is a semiconductor oxide layer, such as indium gallium zinc oxide (IGZO) or other suitable metal semiconductor oxide materials, deposited conformally by atomic layer deposition (ALD), chemical vapor deposition (CVD) or a combination thereof. In the same manner as the odd trenches 80, a dielectric liner layer 81, such as a silicon nitride liner layer, is deposited to cover the channel layer 66 and the remaining volume in the trenches 84 is filled with a sacrificial material 82, such as silicon germanium. After the deposition steps, excess material may be removed from the top of memory structure 50 using, for example, chemical-mechanical polishing (CMP). The resulting memory structure 50 is shown in FIG. 2(f). In some embodiments, annealing is performed after the channel layer is formed in both the even and the odd trenches so that a single annealing step can be used to anneal the channel layer. As thus formed, the first and second conductive layers 62 and 64, in contact with the channel layer 66 in the even and odd trenches, provide the common drain line and the common source line of an HNOR memory string to be formed.

In embodiments of the present disclosure, the memory structure 50 may include non-memory transistors to support operation of the storage transistors. For example, the ferroelectric storage transistors are formed with ferroelectric polarization layers to form non-volatile or quasi-volatile memory transistors. However, to facilitate the operation of the storage transistors, precharge transistors are provided along each memory string and the precharge transistors maybe formed as non-memory transistors. For example, the precharge transistors may be MOSFET devices formed with a gate dielectric layer and not a ferroelectric polarization layer. In some embodiments, the process for fabricating the memory structure 50 of HNOR memory strings further includes fabrication process steps for forming precharge transistors in the HNOR memory strings. In particular, to facilitate the operation of the storage transistors, precharge transistors are provided at given locations along each HNOR memory string where the precharge transistors are used to bias the common source line or the common bit line of a HNOR memory string to a desired voltage. In one example, 3-5 precharge transistors may be provided in a NOR memory strings of 2000 storage transistors.

More specifically, the memory structure 50 of the present invention forms three-dimensional array of NOR memory strings of ferroelectric storage transistors. The ferroelectric storage transistors in each NOR memory string share the common source line and the common drain line (common bit line). The voltage on each shared common source line can be separately applied directly from one or both ends of each source line in the three-dimensional structure. In some embodiments, the shared common source line is electrically floating and the source voltage is applied from the common bit line using precharge transistors so as to obviate the need to provide connector wires to the source lines at the staircase portions of the three-dimensional structure. In one embodiment, the source voltage on a given source line is set to a desired voltage value (such as the ground voltage) through a precharge operation using one or more precharge transistors formed along the memory string and the source line is then left floating after the precharge operation. In particular, the precharge operation set the common bit line to a desired voltage and then the precharge transistor is momentarily turned on to short the common bit line to the common source line to transfer the bit line voltage to the source line. As a result, the common source line is charged from the voltage on the common bit line to a voltage to equal to the bit line voltage. After the precharge operation is complete, the precharge transistor(s) is turned off. The common source line maintains a relatively constant voltage through the parasitic capacitance at the source terminals, such as the parasitic capacitance between the source terminals and the numerous local word line gate terminals of the storage transistors in the NOR memory string.

FIG. 2(g) illustrates the memory structure 50 after the processing steps described above for forming the storage transistors in multiple layers of HNOR memory strings. The HNOR memory strings are formed extending in the Y-direction. At given locations along the memory strings, precharge transistors 112 are provided. The precharge transistors have extended dimensions in the Y-direction to form precharge transistors with a larger channel width to provide sufficient current drive. That is, the precharge transistors have channel width much larger than the channel width of the storage transistors. In some example, the channel width of the storage transistors may be 55nm while the channel width of the precharge transistors may be 220nm (in the Y-direction). In some embodiments, in a memory string of 2000 or more storage transistors, 4-5 precharge transistors may be provisioned along each memory string.

To form the precharge transistors in the memory structure, a mask is applied to the memory structure 50 to cover all of the memory string with mask openings 85 exposing locations where the precharge transistors are to be formed, as shown in FIG. 2(g). In some embodiments, the mask may be a silicon mask. Using the mask defined openings 85, the sacrificial material 82 is removed and the liner layer 81 is also removed, such as by one or more selective wet etch steps. The channel layer 66 remains on the sidewall of the active stacks and will be used to form the channel regions of the precharge transistors. Cavities are formed in the trenches between the active stacks. A gate dielectric layer 86 is then deposited on the sidewalls of the cavities. In one embodiment, the gate dielectric layer 86 is a silicon oxide layer or a hafnium oxide layer. In some examples, the gate dielectric layer 86 is a high temperature oxide (HTO). In another example, the gate dielectric layer 86 may include a high-K dielectric layer, such as 3-5nm of silicon nitride, to fortify the gate dielectric layer. Then, the remaining areas of the cavities, lined with the gate dielectric layer 86, are filled by a conductive layer forming the gate conductor of the precharge transistors. The gate conductor may include successively deposited titanium nitride (TiN) layer 87 and a heavily doped polysilicon or tungsten (W) layer 88. Excess deposited materials may be removed from the top of memory structure 50 by CMP. FIG. 2(g) illustrates the resulting precharge transistors 112 thus formed. View (i) in FIG. 2(g) illustrates the horizontal cross-section along a line B-B’ in the first conductive layer 62 in view (ii). View (ii) in FIG. 2(g) illustrates the vertical cross-section of the precharge transistors along the line B-B’ shown in view (i). In the present embodiment, the precharge transistor 112 is a junctionless metal-oxide-semiconductor (MOS) transistor device.

The fabrication process of memory structure 50 may then return to forming the storage transistors. It is understood that the areas where the precharge transistors are formed are masked or covered, or otherwise protected from the following processing steps. Referring to FIG. 2(h), the sacrificial material 82 and the silicon nitride liner layer 81 are removed, exposing both even and odd trenches 90. The channel layer 66 remains on the sidewalls of the trenches 90. The fabrication process then proceeds to form the gate dielectric layer of the storage transistors. Referring to FIG. 2(i), a gate dielectric layer 67 is deposited onto the sidewalls of the trenches 90. Remaining volume in trenches 90 is filled with a silicon nitride liner layer and a sacrificial material (such as silicon germanium). The liner layer and the sacrificial material is collectively referred to as a sacrificial material 92. The resulting memory structure 50 is shown in FIG. 2(i).

In the present embodiment, the memory structure 50 is used to form ferroelectric storage transistors and the gate dielectric layer 67 is a ferroelectric gate dielectric layer or ferroelectric polarization layer. The ferroelectric polarization layer can be deposited using an atomic layer deposition (ALD) technique and may have a thickness between 2nm to 8nm. A thermal anneal is performed to form the ferroelectric phase in the deposited ferroelectric material. In some cases, the thermal anneal is performed after deposition of a conductive layer on the ferroelectric gate dielectric layer 67. In one embodiment, the ferroelectric gate dielectric layer is formed of a doped hafnium oxide material, such as zirconium-doped hafnium oxide (HfZrO or “HZO”). In other embodiments, the hafnium oxide can be doped with silicon (Si), iridium (Ir) or lanthanum (La). In some embodiments, the ferroelectric gate dielectric layer is a material selected from: zirconium-doped hafnium oxide (HZO), silicon-doped hafnium oxide (HSO), aluminum zirconium-doped hafnium oxide (HfZrAlO), aluminum-doped hafnium oxide (HfO₂:Al), lanthanum-doped hafnium oxide (HfO₂:La), hafnium zirconium oxynitride (HfZrON), hafnium zirconium aluminum oxide (HfZrAlO), and any hafnium oxide that includes zirconium impurities.

In some embodiments, an interfacial layer may be provided between the channel layer 66 and the gate dielectric layer 67. In some embodiments, the interfacial layer is formed using a material with a high dielectric constant (K) (also referred to as “high-K” material), such as a dielectric material with a dielectric constant greater than the dielectric constant of silicon dioxide. In some embodiments, the interfacial layer may be a silicon nitride (Si₃N₄) layer, or a silicon oxynitride layer, or an aluminum oxide (Al₂O₃) layer. Other materials for the interfacial layer 65 may be indium tungsten oxide. In some embodiments, the interfacial layer may be deposited using an atomic layer deposition (ALD) technique and furthermore, in some embodiments, the interfacial layer may be deposited in the same process chamber as the ferroelectric polarization layer, without breaking vacuum between the deposition of the two layers. The interfacial layer may have a thickness of 0.5nm-2nm. In one embodiment, the interfacial layer is an aluminum oxide (Al₂O₃) layer and is annealed to yield an amorphous film with the desired characteristics. In some embodiments, the aluminum oxide (Al₂O₃) layer can be annealed in oxygen (O₂), ozone (O₃), nitrous oxide (N₂O), forming gas (H₂N₂), or argon (Ar).

In the above-described embodiments, the channel layer 66 is formed after each set of odd and even trenches are made (FIG. 2(c) and 2(f)) and then protected by sacrificial materials and subsequently processing removes the sacrificial materials to form the gate dielectric layer 67 on the channel layer 66 (FIG. 2(i)). In some embodiments, the gate dielectric layer can be formed at the same time as the channel layer 66, thereby to avoid oxidation of the channel layer 66 if exposed to oxygen or during elevated temperature anneals. In some cases, the two layers can be formed in the same process chamber without breaking vacuum which makes it more efficient to form the two layers at the same time. Accordingly, in alternate embodiments, in each of the steps above when the channel layer 66 is formed, the gate dielectric layer 67 is formed immediately thereafter and both layers are then protected by the liner layer 81 and the trenches are filled with the sacrificial material 82.

Thereafter, the memory structure 50 is patterned to form the local word line structures. Referring to FIG. 2(j), a mask is applied to the memory structure 50 with openings 94 exposing areas for isolating the storage transistors along a memory string. In embodiments of the present invention, the openings 94 includes a first set of openings 94a defining isolation area between storage transistors. In some embodiments, the openings 94a may be 45nm wide in the Y-direction and the openings 94a may be spaced apart by 55nm. The openings 94 further includes a second set of openings 94b having extended width in the Y-direction. The openings 94b are to be used to perform channel separation in later stage of the fabrication process, as will be described in more details below. In one embodiment, the openings 94b may be 100nm to 120nm wide in the Y-direction. In some embodiments, one opening 94b is provided for every N number of openings 94a. For example, one opening 94b is provided for every 16 openings 94a.

With the openings 94 thus defined, the sacrificial material 92, the gate dielectric layer 67 and the channel layer 66 are removed from the areas defined by the exposed openings, as shown in FIG. 2(j). Shafts 95a are formed from mask openings 94a and shafts 95b are formed from mask openings 94b. In one embodiment, a selective anisotropic etch may be used to form shafts 95a and 95b. In some embodiments, the mask openings 94 overlap the active stacks and the etch process is self-aligned to the edges of the active stacks. FIG. 2(k) is another view of the memory structure 50 illustrating the openings 94a and 94b and the precharge transistors 112 and the shafts 95a and 95b formed therefrom. Referring to FIG. 2(k), storage transistors are formed along each active strip in the Y-direction, in the spaces between adjacent shafts 95a. Extended shafts 95b are formed at selected locations to form access openings for selectively etching the channel layer for channel separation, as will be described in more details below. In some embodiments, one extended shaft 95b is provided is provided for every N number of regular shafts 95a. In one example, the extended shafts 95b are provided once for every 16 regular shafts 95a along the memory string. In another example, the extended shafts 95b may be provided once every 1.6µm along the memory string. As described above, along the memory string, several (e.g. 3-5) precharge transistors 112 (non-memory transistors) are provided to support memory operations in providing biasing of the common source line or common bit line.

In some embodiments, the etching of the channel layer 66 should be performed to limit any unintended sideway etch into the active stacks of active layers 51 at the face of the vertical sidewalls of the trenches that have become exposed to the etchant when the channel layer 66 has been etched away. In some cases, care can be taken to minimize excessive undercutting by sideway etching of the channel layer 66 or the ferroelectric dielectric layer 67.

Referring to FIG. 2(l), the shafts 95a and 95b are filled with a dielectric material 98, forming dielectric filled shafts 98a and 98b. For example, the dielectric material 98 can be a dielectric material, such as silicon oxide (SiO₂). Each pair of dielectric filled shafts 98a define an area in which a pair of ferroelectric storage transistors are to be formed.

In the above-described embodiments, the channel layer 66 is removed during the etch process applied to mask openings 94a and 94b to form shafts 95a and 95b. As shown in FIG. 2(l)(i), the channel layer 66 is separated between adjacent shafts 98 and no channel layer remains in the shafts 98. In other embodiments, the etch process may remove only the sacrificial material 82 and the liner layer 81, without removing the channel layer 66. FIG. 2(l1) illustrates the alternate embodiment where the channel layer 66 is not removed from the shafts 95 and the subsequently formed dielectric filled shafts 98 (including shafts 98a and 98b) are bonded by the channel layer 66 in the X-direction. Accordingly, in memory structure 50a, the channel layer 66 is a continuous layer in the Y-direction along the NOR memory strings. The portions of the channel layer 66 remaining adjacent the dielectric filled shafts 98 have minimal impact on the operation of the storage transistors of the NOR memory strings.

With the dielectric filled shafts 98 thus formed, the fabrication process opens up the dielectric filled shafts 98b to use the inter-layer sacrificial layer 70 to perform separation of the channel layer 66 to each active layer. Referring to FIG. 2(m), the memory structure 50 is masked to protect all areas while exposing the shafts 98b. Then, the dielectric material is removed from shafts 98b, forming cavities 99. In one embodiment, the shafts 98b are etched using a selective anisotropic etch process. Furthermore, in some embodiments, the shafts 98b are etched using the selective anisotropic etch process to remove the dielectric materials in the main portion of the shafts and leaving spacers 98c on the ends of the shafts in the Y-direction to protect the channel layer and the ferroelectric dielectric layer formed in the narrow trenches adjacent the shafts 98b, as shown in FIG. 2(m). A further etch process, such as a selective wet etch process, can be performed to clean the surfaces of the active stacks in the excavated cavities 99. In this manner, the multilayers 51 and the inter-layer sacrificial layer 70 are exposed through the excavated cavities 99. View (i) in FIG. 2(m) illustrates the horizontal cross-section along a line C-C’ in the first conductive layer 62 in view (ii) during the intermediate etch process. View (ii) in FIG. 2(m) illustrates the vertical cross-section of the memory structure 50 along the line C-C’ shown in view (i).

Referring to FIGS. 2(n), using the excavated cavities 99 as access shafts which exposes the multilayer 51 and the inter-layer sacrificial layer 70 from the sides of the active stacks, the fabrication process removes the inter-layer sacrificial layer 70, leaving cavities 102 in places where the inter-layer sacrificial layer used to be. Various removal processes can be used depending on the material used for the third sacrificial layer 70. For example, in the case the sacrificial layer 70 is a carbon layer, the carbon layer can be removed by ashing in an oxygen ambient. In the case the sacrificial layer 70 is amorphous silicon or silicon germanium, a selective wet etch process can be used. The resulting memory structure 50 is shown in FIG. 2(n). With the excavated cavities 102 formed, the remaining multilayers 51 are held in place by being attached to the channel layer 66, the gate dielectric layer 67, and the sacrificial material 92. Furthermore, the active stacks are supported by the dielectric filled shafts 98a formed in the narrow trenches between the active stacks and spaced throughout the length of the memory strings in the Y-direction.

As shown in FIG. 2(n), the excavated cavities 102 thus formed expose portions of the channel layer 66 between the multilayers 51 in the active stacks. In particular, the backside of the channel layer 66 is exposed between each multilayer 51. The cavities 102 can be used as access openings to remove the portions of the channel layer 66 that straddle two adjacent storage transistors formed by adjacent multilayers 51 in the active stack (in the Z-direction). Referring to FIG. 2(o), the fabrication process uses the cavities 102 to selectively etch or remove the exposed portions of channel layer 66, as indicated by the dotted circles in FIG. 2(o). As a result, the channel layer 66 is separated in the Z-direction to each multilayer 51.

More specifically, the fabrication process uses the access openings provided by cavities 99 and cavities 102 to deliver high etch selectivity etchant to the backside of the channel layer 66 to selectively etch the exposed portions of channel layer 66, as indicated by the dotted circles in FIG. 2(o). As a result, the channel layer 66 is separated in the Z-direction to each multilayer 51. In some embodiments, the channel layer 66 is a semiconductor oxide, such as IGZO, and the fabrication process uses, for example, sulfuric acid, citric acid, acetic acid, or ammonium hydroxide (NH₄OH) in a wet etch process to selectively etch the exposed portions of the channel layer 66. In some embodiments, the memory structure 50 includes an interfacial layer between the channel layer and the ferroelectric dielectric layer 67 and the backside etch of the channel layer 66 is selective to the interfacial layer so that the interfacial layer acts as an etch stop for the backside etch process. That is, the exposed portion of the channel layer 66 is etched through the access openings of cavities 99 and cavities 102 and the etch process will stop when the interfacial layer is reached. In one embodiment, the interfacial layer is an aluminum oxide (Al₂O₃) layer. In another embodiment, the backside etch process may be implemented as a multi-step etch process, including an atomic layer etch step used in the removal of the last 1-2nm of the channel layer, in which the atomic layer etch step stops on the interfacial layer or stop on the ferroelectric dielectric layer 67.

In the embodiment shown in FIG. 2 ( o ) the channel separation process stops when the exposed portions of the channel layer 66 are removed and the channel region is physically separated and isolated to each active layer 51 in each active stack. In some embodiments, the channel separation process can continue, by a change of etchant chemistry or process, to remove the now exposed portions of the ferroelectric dielectric layer 67 , as shown in FIG. 2 ( o 1 ) . In memory structure 50 b of FIG. 2 (o 1 ) , the ferroelectric dielectric layer 67 , serving as the ferroelectric polarization layer of the storage transistors, is also physically separated and isolated to each active layer 51 in each active stack. The separation of the ferroelectric dielectric layer 67 is optional and may be omitted in other embodiments of the present invention. In some cases, care can be taken to minimize excessive undercutting by sideway etching of the channel layer 66 or the ferroelectric dielectric layer 67 .

Referring to FIG. 2(p), after the channel separation process, the exposed surfaces of the memory structure 50 can be passivated, such as by forming a thin liner layer 104. The liner layer 104 is a thin dielectric layer, such as around 1-2nm thick. The liner layer 104 can be a silicon oxide layer, a silicon nitride layer or an aluminum oxide layer and serves to passivate or seal the exposed surfaces in the cavities 102. The remaining portions of cavities 102 can be left unfilled and used as an air gap isolation layer. Alternately, the remaining portions of cavities 102 can be filled with a dielectric material, such as silicon dioxide. Furthermore, in the present embodiment, the excavated cavities 99 are provided with the liner layer 104 and are left unfilled to use as an air gap isolation. In other embodiments, the cavities 99 can be filled with a dielectric material, such as silicon dioxide.

Referring to FIG. 2(q), the sacrificial material 92, including any filler or liner material, is removed from the trenches 90, using a suitable selective wet or dry etch process. As a result, the ferroelectric dielectric layer 67 is exposed in the regions between adjacent dielectric filled shafts 98a. Referring to FIG. 2(r), the excavated cavities between adjacent shafts 98a are then filled with a conductive layer which forms the gate conductor layer 68.

In the present embodiment, the gate conductor layer 68 is a metal layer and can include successively deposited thin conductive liner 68a and conductive filler material 68b. The thin conductive liner 68a may be a titanium nitride (TiN) liner or a tungsten nitride (WN) liner. The thin liner layer 68a may be formed using, for example, an atomic layer deposition (ALD) technique. The conductive filler material 68b may be a metal, such as tungsten (W) layer or molybdenum (Mo), or heavily doped n-type or p-type polysilicon. The conductive filler material 68b may be deposited using CVD or PECVD techniques.

Between each pair of dielectric-filled trenches 98a, the conductive layer 68 provides a vertical local word line (LWL) that serves as gate electrode for each of the storage transistors that are vertically aligned in the same active stack. The structure resulting from the combination of the gate dielectric layer 67 and the conductive layer 68 is referred herein as the local word line (LWL) structure. Excess deposited materials may be removed from the top of memory structure 50 by CMP. A cap oxide layer 106 may be formed above the memory structure 50. FIG. 2(r) illustrates the resulting memory structure 50. The memory structure 50 thus formed includes storage transistors arranged in NOR memory strings in multiple planes. In particular, the storage transistors have the same structure as the storage transistor 20 as described in FIG. 1.

Vias and interconnects are formed in and above the cap oxide layer 106 to form interconnection between the storage transistors and the control circuitry, such as the CuA formed in the substrate 52. For example, the bit lines and local word lines of the memory stack are connected with control, select, and sense circuits that are formed in the CuA in the semiconductor substrate. In one example, global word lines, formed using copper metallization processes and materials, can be formed above the cap oxide layer 106 to connect the local word lines 68 to the respective word line drivers formed in the CuA in the substrate 52. FIG. 2(s) illustrates the memory structure 50 with a global word line metallization layer 114 formed on the cap oxide layer 106 and connected to local word lines 68 formed in the memory structure through vias 112 formed in the cap oxide layer 106. In some embodiments, the global word line metallization layer 114 is one of copper, tungsten, molybdenum, cobalt, or other metals, or compounds thereof. Vias 112 is filled with a metal layer, such as copper or other suitable metals. As thus configured, each global word line 114 is connected to a group of local word lines 68 to provide the control signal to the gate electrodes of the storage transistors formed in multiple memory planes associated with the respective vertical local word lines. More specifically, the global word lines 114 runs in the X-direction, perpendicular to the common bit lines 62 which runs in the Y-direction. Each global word line connects to the local word lines arranged in a row across the X-direction, as shown in FIG. 2(s)(i). Meanwhile, the bit lines from different memory planes of each active stack are connected to bit line selectors through a staircase structure provided in the Y-direction. The bit line selectors connect the bit lines to their respective sense amplifiers and voltage drivers circuit formed in the CuA, typically formed under the staircase structure.

It is instructive to note that FIG. 2(s) is illustrative only and is not intended to depict the exact vias and global word line interconnect structures. For example, the vias 112 connecting the local word lines 68 to the global word lines 114 need to be isolated from the channel layer so as not to short the gate electrode to the channel region of the storage transistors. Various methods for forming the vias 112 while providing isolation are possible. In one example, the channel layer 66 may be recessed from the top of the memory array. In another example, additional dummy layers maybe included in the memory structure above the array (in the Z-direction) to terminate the channel layer while extending each gate conductor layer 68 for connection to a via 112.

In the embodiment shown in FIG. 2(s), as a result of the channel separation process in the Z-direction using the cavities 102 and as a result of the shafts 98a formed between the LWL structures, each storage transistor thus formed is isolated in the Z-direction from other storage transistors in other planes of the same active stack. Each storage transistor is also isolated in the Y-direction from other storage transistors by the dielectric filled shafts 98a. Each storage transistor in the memory structure 50 is therefore completely isolated to enhance the performance characteristics of the storage transistors. Furthermore, air gap isolation is used to isolate the storage transistors in the active stacks between memory planes where the air gaps provide better isolation characteristics than most dielectric materials.

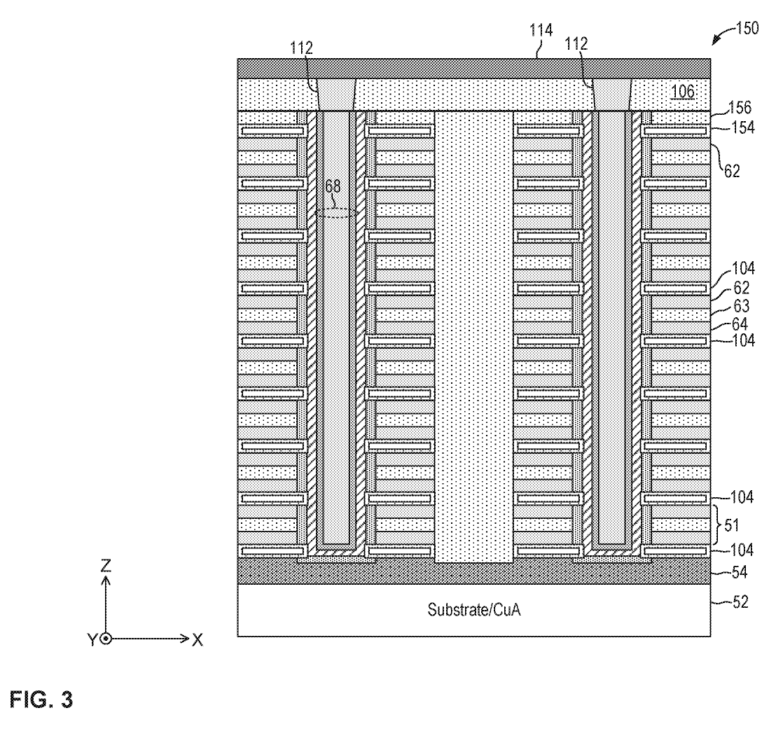

FIG. 3 illustrates a memory structure formed using dummy layers for isolating the channel layer for global word line connections in some embodiments. Referring to FIG. 3, the memory structure 150 includes a dummy isolation layer 154 and a dummy dielectric layer 156. In the initial stack formation, the dummy isolation layer 154 can be provided as an inter-layer sacrificial layer described above (e.g. FIG. 2(a)) which is subsequently replaced by the inter-layer isolation layer, such as an air gap isolation. The dummy dielectric layer 156 functions as a capping layer for the dummy isolation layer 154 during the replacement process. In particular, during intermediate processing steps, the dummy isolation layer 154, as an inter-layer sacrificial layer, is removed to provide access openings to the backside of the channel layer 66. The channel layer 66 is selectively etched through the access openings. Then, the liner layer 104 is formed around the exposed cavities of the dummy isolation layer 154, the remaining portion forming an air gap isolation. As thus constructed, the channel layer for the topmost memory strings in the memory structure 150 is separated and isolated by the dummy isolation layer 154. A cap oxide layer 106 is formed above the memory structure 150. Vias 112 can be formed to contact the local word lines (gate conductor layer 68) without concern for possible electrical shorts to the channel layer. A metallization layer is formed on the cap oxide layer 106 to form the global word lines. Each global word line connects to the local word lines through vias 112 to provide the control signal to the gate electrodes of the storage transistors formed in multiple memory planes associated with the respective vertical local word lines.

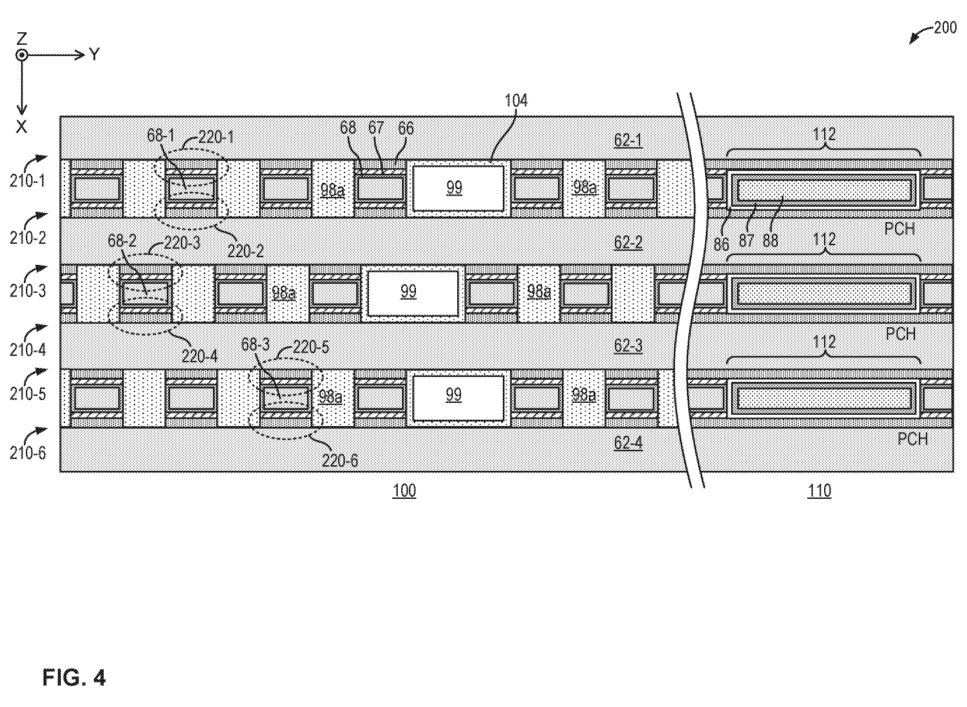

FIG. 4 is a cross-sectional view of a portion of a memory structure in the X-Y plane illustrating NOR memory strings with precharge transistors in embodiments of the present invention. Referring to FIG. 4, a memory structure 200 includes active stacks bordering narrow trenches with local word line structures formed therein. In the present illustration, the cross-sectional view is taken at the first conductive layer 62 of a given active layer in an active stack. The first conductive layer 62 forms the common bit line of the memory string. A ferroelectric storage transistor 220 is formed at the intersection of the common bit line 62 with the channel layer 66, the gate dielectric layer 67 and the gate conductor 68. FIG. 4 illustrates six memory strings 210-1 to 210-6 that are formed extending in the Y-direction along four active stacks (represented by respective first conductive layer 62-1 to 62-4). For example, each memory string 210 includes the storage transistors 220 formed along the active stack 62 and intersecting with all of the local word line structures along the active stack 62. The storage transistors 220 are isolated from other storage transistors in the memory string by the dielectric filled shafts 98a. Access shafts with cavities 99 lined with the liner layer 104 are used during the fabrication process to perform channel separation to isolate the channel layer 66 to each memory plane (in the Z-direction). Cavities 99 are left unfilled in the present embodiment and can function as an air gap isolation. Precharge transistors 112 are formed along each memory string to support the precharge operation.

It is instructive to note that in memory structure 200, a pair of memory strings 210 in each memory plane bordering a narrow trench including LWL structures have corresponding storage transistors sharing a local word line. Accordingly, each local word line activates two storage transistors in the memory strings bordering the same LWL structure in each memory plane. In one example, in response to the local word line 68-1 being selected, storage transistors 220-1 and 220-2 associated with respective memory strings 210-1 and 210-2 are activated. The common bit lines 62-1 and 62-2 are in turn selected to provide access and the appropriate voltages to the activated storage transistors 220-1 and 220-2. In another example, in response to the local word line 68-2 being selected, storage transistors 220-3 and 220-4 associated with respective memory strings 210-3 and 210-4 are activated. The common bit lines 62-3 and 62-4 are in turn selected to provide access and appropriate voltages to the activated storage transistors 220-3 and 220-4. In some embodiments, when storage transistor 220-1 is to be erased, transistor 220-2, which may be in a programmed state, needs to be protected from being erased as well. As an example of a typical erase operation of a ferroelectric storage transistor 220-1, the erase operation may require 3.0 Volts applied to the local word line 68-1, and 0.0 Volts applied to its bit line 62-1. To prevent erasing of ferroelectric transistor 220-2 (that shares the same local word line 68-1 and therefore has the same 3.0 Volts on its control gate), its bit line 62-2 must be held at an inhibit voltage Vinhb that is close enough to 3.0V to avoid flipping of the polarization state of ferroelectric type storage transistor 220-2. The same applies to all program and program inhibit operations, as well as for inhibiting disturbing the stored data of storage transistors on different planes above or below the plane being accessed, that are not being addressed yet are still being exposed to the voltage on their shared local word lines.

### Enhanced Fringing Field Effect

In the memory structure 10 of FIG. 1, the channel length of the ferroelectric storage transistor 20 thus formed is determined by the thickness L1 of the channel spacer dielectric layer 23. In embodiments of the present invention, shorter channel lengths, such as L1 less than 10nm, can accentuate the electric fringing-field effect of the ferroelectric storage transistor which enhances the polarization effect in the ferroelectric dielectric layer. Referring again to FIG. 1, when erase or program voltages are applied between the bit line (BL) electrode 22 and the control gate electrode 28, the electric field between the two electrodes is imposed onto the part of the ferroelectric dielectric layer 27 that is directly opposite the BL electrode to cause the desired change in polarization in the ferroelectric dielectric layer 27. The electric field further includes fringing field that extends into part of the channel 26.

In some embodiments, the fringing electric field is further accentuated by biasing the bit line (BL) and the source line (SL) to the same voltage during erase and program operations. In other words, the bit line (BL) and the source line (SL) of the ferroelectric storage transistor is being used as a single electrode during the erase and program operations. With the bit line and the source line biased as a single electrode, the fringing electric fields from both the bit line 22 and the source line 24 extends into the channel 26 from both ends and the fringing electric field overlaps most of, or the entire length of, the channel 26 when the channel is sufficiently short. By biasing the ferroelectric storage transistor in a single electrode mode to accentuate the fringing electric field, the polarization of the ferroelectric dielectric layer is enhanced which can result in a wider threshold voltage window between the erase and program states.

In one embodiment, when the memory structure implements the floating source architecture, the precharge transistors described above can be used to facilitate the equalization of the voltages of the bit line 22 and the source line 24 during erase or program operations so that the bit line 22 and the source line 24 operates as a joint electrode to maximize the fringing field coverage of ferroelectric dielectric layer 27.

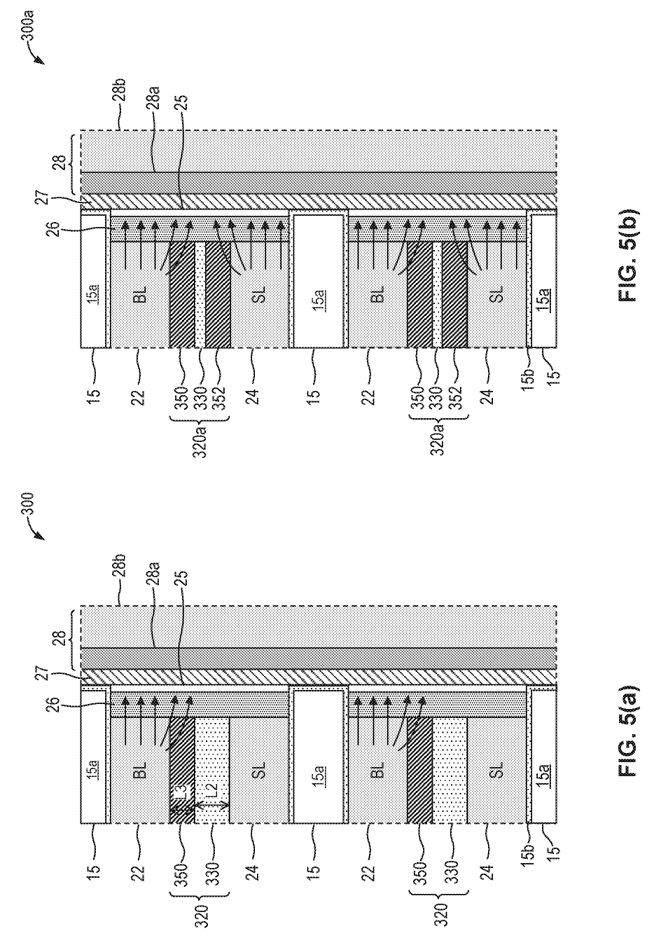

In another embodiment of the present invention, the fringing electric field is enhanced by using a high dielectric constant (high-K) dielectric layer in the channel spacer region adjacent the bit line. In particular, the fringing electric field is enhanced by using a high dielectric constant (high-K) dielectric layer in the channel spacer region adjacent the bit line. FIGS. 5(a) and 5(b) illustrate the detail construction of junctionless ferroelectric storage transistors in alternate embodiments of the present invention. Like elements in FIGS. 1 and 5(a) and 5(b) are given like reference numerals and may not be further described in detail. Referring first to FIG. 5(a), a ferroelectric storage transistor 300 includes a bit line 22 forming the common drain line of the NOR memory string, and a source line 24 forming the common source line of the NOR memory string, the bit line 22 and the source line 24 being spaced apart by a channel spacer dielectric layer 320. The storage transistor 300 further includes a semiconductor oxide channel layer 26 formed vertically along the sidewall of the memory stack and in contact with both the bit line 22 and the source line 24. A ferroelectric dielectric layer 27 and a gate conductor layer 28 are formed on the sidewall of the memory stack adjacent the channel layer 26. In some embodiments, an optional interfacial layer 25 may be provided between the channel layer 26 and the ferroelectric dielectric layer 27. The storage transistor 300 is isolated from adjacent storage transistors in the stack by an inter-layer isolation layer 15, which can be an air-gap isolation layer. As thus configured, the storage transistors 300 are junctionless ferroelectric storage transistors.

In embodiments of the present invention, the channel spacer dielectric layer 320 includes a first dielectric layer 330 and a second dielectric layer 350 formed between the bit line 22 and the first dielectric layer 330. The second dielectric layer 350 has a higher dielectric constant than the first dielectric layer 330 and is referred to as a high dielectric constant (high-K) dielectric layer in the present description. By incorporating the high-K dielectric layer 350 adjacent the bit line 22, the fringing electric field between bit line electrode 22 and the gate electrode 28 is concentrated in the portion of the channel 26 closest to the bit line 22, which has the effect of enhancing the polarization effect of the ferroelectric polarization layer 27 during program and erase operations.

In some embodiments, the high-K dielectric layer 350 can be formed using silicon nitride (having a dielectric constant of about 6) or hafnium oxide (having a dielectric constant of about 19). Meanwhile, the first dielectric layer 330 can be formed using silicon dioxide (having a dielectric constant of 3.9). In some embodiments, the first dielectric layer 330 has a thickness L2 and the high-K dielectric layer 350 has a thickness L3 and the ferroelectric storage transistor 300 has an effective channel length of L2+L3. In one example, the thickness L2 is 15nm and the thickness L3 is 10nm, and the effective channel length of the storage transistor 300 is 25nm. The high-K dielectric layer 350 may be provided in the fabrication process by including the high-K dielectric layer in the deposition process forming the multilayer stack, such as described with reference to FIG. 2(a).

The higher dielectric constant of the high-K dielectric layer 350 serves to concentrate the fringing electric field that extend over the channel 26 when polarization voltage is applied between the bit line electrode 22 and the control gate electrode 28. The accentuation of the fringing electric field is particularly effective if the bit line conductive layer 22 is very thin (e.g. 20nm or less), in which case any contribution to the electric field from the field fringing into channel 26 is reinforcing the polarization effect during erase or program operation.

In the embodiment shown in FIG. 5(a), the high-K dielectric layer 350 is provided only adjacent the bit line conductive layer 22. In other embodiments, as shown in FIG. 5(b), a channel spacer dielectric layer 320a may include a first high-K dielectric layer 350 provided adjacent the bit line conductive layer 22 and a second high-K dielectric layer 352 provided adjacent the source line conductive layer 24. A narrow dielectric layer 330 may separate the first and second high-K dielectric layers 350, 352. In the present embodiment, the dielectric layer 330 is formed of a material with a dielectric constant lower than the dielectric constant of the dielectric layers 350 and 352. In alternate embodiments, the entire channel spacer dielectric layer can be formed entirely of a high-K dielectric layer, such as a dielectric layer with a dielectric constant larger than the dielectric constant of a silicon oxide layer.

In the above-described embodiments, the memory structures are formed using a semiconductor oxide layer as the channel layer of the storage transistors. In some embodiments, the semiconductor oxide channel layer is formed as a bi-layer channel including a first semiconductor oxide layer formed on the trench sidewalls and in good electrical contact with the conductive layers forming the drain and source lines and a second semiconductor oxide layer formed on the first semiconductor oxide layer. The first and second semiconductor oxide layers together form the channel layer and providing the channel region to each storage transistor. The first semiconductor oxide layer functions as a low contact resistance contact layer to the drain and source conductive layers to which it contacts. The second semiconductor oxide layer functions as the main channel layer providing the desired high mobility and high on-current for the channel region of the storage transistors. In some embodiments, the first semiconductor oxide layer is a metal oxide semiconductor material that provides a contact resistance to the conductive layers that is lower than the contact resistance provided by the second semiconductor oxide layer. In one embodiment, the first semiconductor oxide layer is, for example, an indium aluminum zinc oxide (InAlZnO or IAZO) layer of thickness around 1nm-2nm, and the second semiconductor oxide layer is an IGZO layer of thickness around 6nm. In other embodiments, other semiconductor oxide materials that provide a desirably low contact resistance to metal layers can be used as the first semiconductor oxide layer. In particular, a metal oxide semiconductor material that has high immunity to deoxidization of the channel layer by the source/drain conductive layer and suppresses oxidation of the source/drain conductive layers during thermal processing is desired for use as the first semiconductor oxide layer.

In the present description, spatially relative terms, such as “beneath,” “below,” “lower,” “above,” “upper” and the like, are used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present.

In this detailed description, process steps described for one embodiment may be used in a different embodiment, even if the process steps are not expressly described in the different embodiment. When reference is made herein to a method including two or more defined steps, the defined steps can be carried out in any order or simultaneously, except where the context dictates or specific instruction otherwise are provided herein. Further, unless the context dictates or express instructions otherwise are provided, the method can also include one or more other steps carried out before any of the defined steps, between two of the defined steps, or after all the defined steps

In this detailed description, various embodiments or examples of the present invention may be implemented in numerous ways, including as a process; an apparatus; a system; and a composition of matter. A detailed description of one or more embodiments of the invention is provided above along with accompanying figures that illustrate the principles of the invention. The invention is described in connection with such embodiments, but the invention is not limited to any embodiment. Numerous modifications and variations within the scope of the present invention are possible. The scope of the invention is limited only by the claims and the invention encompasses numerous alternatives, modifications, and equivalents. Numerous specific details are set forth in the description in order to provide a thorough understanding of the invention. These details are provided for the purpose of example and the invention may be practiced according to the claims without some or all of these specific details. For the purpose of clarity, technical material that is known in the technical fields related to the invention has not been described in detail so that the invention is not unnecessarily obscured. The present invention is defined by the appended claims.

1. A process suitable for use in fabricating a memory structure comprising storage transistors of a NOR memory string above a planar surface of a semiconductor substrate, the process comprising:
above the planar surface, repeatedly depositing, alternately and one over another, a multilayer and an inter-layer sacrificial layer, each multilayer comprising first and second sacrificial layers and a first isolation layer between the first and second sacrificial layers;
forming a first plurality of trenches in the multilayers and the inter-layer sacrificial layers, each trench having (i) a depth that extends along a first direction that is substantially normal to the planar surface, (ii) a length that extends along a second direction that is substantially parallel to the planar surface, (iii) a width that extends along a third direction that is substantially orthogonal to the depth and the length, the length of the trench being substantially greater than its width;
forming an oxide semiconductor layer on the sidewalls of the first plurality of trenches;
forming a second plurality of trenches in the multilayers and the inter-layer sacrificial layers, each trench in the second plurality of trenches having substantially the same depth, length and width as the first plurality of trenches, and wherein the first and second plurality of trenches divide the multilayers into a plurality of stacks of multilayer strips, each stack being separated from an adjacent stack by one of the trenches;
replacing the first and second sacrificial layers with first and second conductive layers; and
forming the oxide semiconductor layer also on the sidewalls of the second plurality of trenches.

2. The process of claim 1, further comprising:
filling the trenches with a sacrificial filler material;
cutting a plurality of openings in the semiconductor oxide layer and the sacrificial filler material of each trench, the openings comprising first openings and second openings, each second opening being longer than each first opening in the second direction;
removing the inter-layer sacrificial layer through the second openings, thereby forming access openings exposing portions of the oxide semiconductor layers in the plurality of stacks; and
removing the exposed portions of the oxide semiconductor layer through the second openings and the access openings.

3. The process of claim 2, wherein cutting the plurality of openings in the semiconductor oxide layer comprises:
providing one second opening for every N number of first openings along the second direction.

4. The process of claim 2, further comprising:
forming a ferroelectric gate dielectric layer on the oxide semiconductor layer in the first and second plurality of trenches; and
subsequent to removing the exposed portions of the oxide semiconductor layer through the access openings, removing exposed portions of the ferroelectric gate dielectric layer through the second openings and the access openings.

5. The process of claim 2, further comprising:
forming a dielectric liner layer on the exposed surface of the memory structure in the access openings and the second openings.

6. The process of claim 2, further comprising:
filling the first openings with a dielectric layer to form the dielectric filled shafts.

7. The process of claim 6, further comprising:
forming gate electrode structures in the first and second pluralities of trenches, each gate electrode structure being formed between adjacent dielectric filled shafts.

8. The process of claim 7, wherein forming the gate electrode structures comprises:
removing the sacrificial filler materials from each trench between the dielectric filled shafts; and
depositing a ferroelectric gate dielectric layer in contact with the oxide semiconductor layer on the sidewalls of the first and second pluralities of trenches; and
forming a conductive layer in the remaining excavated cavities between adjacent dielectric filled shafts.

9. The process of claim 8, further comprising:
forming an interfacial layer between the semiconductor oxide layer and the ferroelectric gate dielectric layer.

10. The process of claim 9, wherein the ferroelectric gate dielectric layer comprises a doped hafnium oxide layer and the interfacial dielectric layer comprises a high dielectric constant dielectric layer.

11. The process of claim 1, further comprising:
forming the oxide semiconductor layer in the first plurality of trenches and followed by forming a ferroelectric gate dielectric layer on the oxide semiconductor layer; and
forming the oxide semiconductor layer in the second plurality of trenches and followed by forming a ferroelectric gate dielectric layer on the oxide semiconductor layer, wherein the ferroelectric gate dielectric layer is formed on the oxide semiconductor layer before the trenches are filled with a sacrificial filler material.

12. The process of claim 8, wherein the oxide semiconductor layer comprises one of an indium gallium zinc oxide (IGZO) layer, an indium zinc oxide (IZO) layer, an indium tungsten oxide (IWO) layer, or an indium tin oxide (ITO) layer.

13. The process of claim 8, wherein the ferroelectric gate dielectric layer comprises a doped hafnium oxide layer.

14. The process of claim 12, wherein forming the oxide semiconductor layer on the sidewalls of the first plurality of trenches and the second plurality of trenches comprises:
forming the oxide semiconductor layer comprising a first oxide semiconductor layer and a second oxide semiconductor layer, the first oxide semiconductor layer being provided in contact with the first and second conductive layers and providing a contact resistance to the first and second conductive layers lower than the contact resistance of the second oxide semiconductor layer.

15. The process of claim 1, wherein the first and second conductive layers each comprises a metal layer.

16. The process of claim 1, wherein the first isolation layer comprises a silicon oxide layer.

17. The process of claim 1, wherein the first isolation layer comprises a first dielectric layer having a first dielectric constant formed adjacent the first conductive layer and a second dielectric layer having a second dielectric constant formed adjacent the second conductive layer, the first dielectric constant being larger than the second dielectric constant.

18. The process of claim 1, wherein the first isolation layer comprises a first dielectric layer having a first dielectric constant formed adjacent the first conductive layer, a second dielectric layer having a second dielectric constant formed adjacent the second conductive layer, and a third dielectric layer having a third dielectric constant formed between the first and second dielectric layers, the first and second dielectric constants being larger than the third dielectric constant.

19. The process of claim 1, wherein the first isolation layer comprises a dielectric layer having a dielectric constant greater than a dielectric constant of silicon oxide.

20. The process of claim 8, wherein forming the gate electrode structures comprises forming the gate electrode structures in the first plurality of trenches that are offset in the second direction from the gate electrode structures in the second plurality of trenches.
